(19) United States
(12) Patent Application Publication
(10) Pub. No.: US 2007/0243678 A1
(43) Pub. Date: Oct. 18, 2007

(54) Inkjet printing of cross point passive matrix devices

(75) Inventors: Christopher Newsome, Cambridgeshire (GB); Daping Chu, Cambridgeshire (GB)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/727,349

(22) Filed: Mar. 26, 2007

(30) Foreign Application Priority Data
Mar. 31, 2006 (GB) 0606592.4

(51) Int. Cl. H01L 21/8244

(52) U.S. Cl. 438/238

(57) ABSTRACT

A method of manufacturing a cross-point device, comprises: providing at least one first electrode on a substrate; providing first regions of an electrically functional material over the at least one first electrode; and providing at least one second electrode over the at least one first electrode and the plurality of regions of electrically functional material, whereby the first and second electrodes form a plurality of intersections with the electrically functional material between them. At least two intersections have separate regions of electrically functional material between the first and second electrodes.

### FIELD OF THE INVENTION

The current invention relates, among other things, to the formation of a cross point structure for the application of a passive matrix memory array.

### BACKGROUND OF THE INVENTION

Inkjet printing technology has been implemented for electronic component fabrication on a research & development scale for a number of years. Most notably, light emitting diodes fabricated from organic semiconducting polymers have been produced on large scales using inkjet printing. In particular, flat panel organic light emitting displays (OLEDs) and thin film transistors (TFTs) have been developed using inkjet printing techniques in combination with other techniques, such as the formation of bank structures.

In addition to the above components, similar fabrication techniques to produce memory systems are of great interest. As for the inorganic counterparts of light emitting diodes and transistors, the fabrication route to inorganic memory cells and chips requires high temperature processing and high vacuum deposition systems. Such fabrication routes are costly to establish and require high degrees of maintenance and thus further costs. It would be desirable to minimise such expenditures and improve efficiency.

Cross point arrays can be used to form memory systems. The fundamental structure of a ferroelectric memory cross point array is, in its simplest form, an array of thin film “capacitors” as shown in FIG. 1. Each “capacitor” stores the written polarity.

Specifically, FIG. 1a shows a cross-point structure comprising two electrodes 10, 11, which are applied either side of a thin ferroelectric film 20, typically in the range of 200 nm to 2 microns in thickness, using metallic materials. Upon application of an electric field between the electrodes 10, 11, a polarisation response can be measured as a function of the electric field. A hysteretic nature in the polarisation vs. field plot will indicate the suitability of the material for a memory device.

An example of a ferroelectric memory is shown in FIG. 1b, in which a plurality of rows of electrodes 10a are provided under the ferroelectric film 20 and a plurality of columns of electrodes 10b are provided above the ferroelectric film. In a manner well-known in the art, the rows and columns of electrodes can be addressed to polarise the ferroelectric material at the intersection between an addressed row and an addressed column, thereby writing data. This data can subsequently be read by determining the polarisation of the ferroelectric material at the intersection between the addressed row and column.

More specifically, at each cross point, the top and bottom electrodes form a “bit” in a memory device, and can be read as a “1” or a “0” according to the spontaneous polarisation of the ferroelectric material. The spontaneous polarisation of a ferroelectric material is given by the value of the dipole moment per unit volume of material. In a ferroelectric material, the direction of the spontaneous polarisation can be switched by the electric field, and hence a polarisation hysteresis can be measured.

The ferroelectric material in the case of an organic polymer material could be poly(vinylidene fluoride) (PVDF) or poly(vinylidenefluoride-trifluoroethylene) (P(VDF-TrFE)) or poly(vinylidenefluoride-tetrafluoroethylene) (P(VDF-TeFE)) or others. A typical film thickness for the material is in the range of 200 to 2000 nm. Polar solvents can be used to spin coat this material. For such a coating process a solvent with a boiling in the range of (80 to 140° C.) is preferable, such that after the spin coating process, the majority of the original solvent evaporates in ambient conditions. A solvent such as 2-butanone (also known as methyl ethyl ketone) may be used. Such a solvent produces films with high thickness uniformity.

The electrodes defining the area of the ferroelectric capacitor can be made from a number of materials. In the case of evaporated metals, gold, aluminium or silver can be easily thermally evaporated. This selection of metals is just a few of many that could be utilised. In the interests of the reduction in cost, aluminium is a primary choice. In order to minimise the disturbance to the ferroelectric material from solution processing, the top electrode definition is most preferably performed by a direct patterning of an evaporated metal through a shadow mask. For a photolithographically defined top electrode, photoresist materials are required in direct contact with the ferroelectric layer. Such a combination of materials may result in inter-diffusion or intermixing due to the host solvent of the photoresist, or also the developer and remover for the photoresist. By using a shadow mask for this electrode definition, the disturbance to the ferroelectric layer will be minimal. Some heating of the film may occur due to the nature of the evaporation of the metal source.

Organic memory elements have already been fabricated using organic materials as the active layer, ie using a polymer material as the ferroelectric dielectric in a capacitor structure. The advantage of using a polymer as the ferroelectric layer is that the material can be deposited from a solution by spin coating in ambient conditions. Further processing to remove the host solvent can be achieved by using low temperature drying (<150° C.). Although this technique has been used to deposit the ferroelectric layer, the deposition of the metal electrodes has been widely achieved using thermal evaporation to define the dimensions of the capacitor. Although a high device performance can be expected by using this electrode deposition technique, full cost minimisation is still not achieved is this case.

US2004209420 describes the formation of inorganic electrodes (and in particular focuses on the deposition of top electrodes) for an organic polymer cross point array. The electrodes in the device consist of a metal (namely titanium) deposited by evaporation in a vacuum. However, no inkjet printing techniques are employed in this disclosure.

JP2004040094 describes the use of a polymer ferroelectric material as a dielectric on an organic semiconductor to form an organic ferroelectric thin film transistor. Such a “Ferro-OTFT” can be implemented in an active matrix array.

WO03107426 outlines the use of an organic semiconductor film rather than a ferroelectric material as the active medium in a passive matrix cross point array. The semiconductor film contains an organic dopant, the concentration of which may be varied to “tune” the desired characteristics of the cross points.

Fluorinated polymers such as that mentioned above may be used in ferroelectric capacitors, and are soluble in polar solvents such as 2-butanone. The high electronegativity of the fluorine atoms in the structure gives rise to this high polarity of the material, and therefore solubility in such a solvent. In addition to a high polarity, the fluorine content in these polymers also gives rise to a strong hydrophobic nature and an olio-phobic nature for a fully fluorinated material. The contact angle of a water droplet on the surface of a thin film of this type of polymer is equal to or greater than 90 degrees. By exhibiting such a high contact angle, it is problematic to deposit or print a water based dispersion or solution of material on such a surface.

PEDOT:PSS is widely used as a conducting polymer in many organic devices, as explained above. PEDOT:PSS is widely and commercially available, for example in the form of Baytron-P solution, produced by H C Starck. The commercial Baytron-P solution is a water-borne solution of poly(ethylene dioxylthiophene) (PEDOT) in the presence of poly(styrene sulphonic acid) (PSS), which serves as a colloid stabiliser and dopant. Thus, the material is a dispersion of particles (in the nanometre scale) based in water and, consequently, when this material is deposited on the surface of a PVDF (or a co-polymer) film, the same de-wetting behaviour is exhibited.

This problem has been previously recognised and is addressed in WO 02/43071. Specifically, WO 02/43071 discloses a ferroelectric memory circuit comprising a ferroelectric memory cell in the form of a ferroelectric polymer thin film and first and second electrodes on either side. The electrodes are conducting polymer electrodes which are deposited on top of a ferroelectric thin film by spin coating from an H C Starck Baytron-P solution or dipping in such a solution. WO 02/43071 discloses that in the case of spin coating a certain amount of surfactant must be added to the Baytron-P solution to allow a uniform and smooth PEDOT/PSS film formation. However, neither the amount nor the nature of the surfactant to be added to the spin coating solution is disclosed in WO 02/43071.

WO 2005/064705 also discloses a ferroelectric device in which an aqueous PEDOT:PSS solution is deposited by spin coating on a ferroelectric polymer layer. To overcome the de-wetting properties of ferroelectric polymer layer, n-butanol is added in the aqueous solution as a surface-tension reducing agent with a concentration of 3% or lower, so that the solution remains in a single phase. In addition, a cross-linking agent may be provided in the aqueous solution.

Hitherto, and in both WO 02/43071 and WO 2005/064705, the PEDOT:PSS is deposited on the ferroelectric layer by spin coating or dipping so that it covers the whole surface of the ferroelectric layer. Subsequently, the PEDOT:PSS layer is patterned using known techniques, such as photolithography.

However, the use of such patterning techniques is undesirable as they require the highly accurate alignment of a mask over the layer to be patterned. Where it becomes necessary to pattern several layers, which is common in the formation of electronic devices or circuits, such as transistors and ferroelectric devices, difficulties with alignment are increased. Thus, the speed of manufacture is reduced and the cost of the devices is increased.

In addition, as an alternative to thermally evaporating metals in a vacuum, inkjet printable dispersions or solutions of polymers can be inkjet printed. In addition, metal colloidal dispersions can be prepared in solvents with a sufficiently small constituent particle size (typically <100 nm) such that they can be inkjet printed in ambient conditions.

By replacing the evaporated metals for the top and bottom contacts in the ferroelectric capacitor by solution processible conducting materials, it is possible to realise a fully functional cross point device. The selection of the materials for the electrodes is primarily determined by the formulation of the ink in which the colloid is prepared. In the case of polyethylene dioxythiophene (PEDOT) doped with polystyrene sulphonic acid (PSS), a water borne suspension is typical. The PSS is soluble in water, thus acting to disperse the PEDOT (otherwise water disliking) into a suspension. Such a material can be printed readily on many surfaces as a bottom electrode.

Modification of the water suspension in order to allow for the hydrophobicity of the ferroelectric material is disclosed in British patent application no. 0525449.5, in which a surface tension reducing agent is added to the water based solution in order to reduce the contact angle to a hydrophobic surface. By using this method, continuous tracks of material may be deposited on a spin coated ferroelectric film, thus allowing the completion of a top electrode.

A second technique in producing a sufficiently wetting surface for an aqueous based conducting ink is to deposit a hydrophilic layer from a solution by spin coating. A poly(vinyl phenol) (PVP) film on top of the ferroelectric P(VDF-TrFE) layer can be used to modify the contact angle such that a track of a water borne conducting material such as PEDOT:PSS or a metal colloid can be printed. The thickness of such a layer can be very thin (ie as thin as 10 nm) to be effective over large areas (ie several square centimetres). The native contact angle of a water based material on the P(VDF-TrFE) surface is 90°. By depositing a layer of PVP, this can be reduced to 30°. Such a contact angle is an ideal value, as an extremely wetting surface (<10° contact angle) will result in wide tracks upon the lateral spreading of inkjet printed droplets. Such a spreading is useful for filling areas such as pixel electrodes for a display element for example, but is not always preferable for conducting tracks and interconnections for a cross point device.

An attractive aspect of forming electronic devices using organic materials is the possibility of using flexible substrates, and reel-to-reel processing. However, the difficulties in the alignment required by patterning techniques are exacerbated and become prohibitive.

In the known fabrication procedures for cross point devices, the electrically functional active material (that is, the ferroelectric or semiconductor material) is deposited using spin coating or other conventional CMOS-type fabrication steps. Moreover, spin coating and/or CVD, other evaporation or photolithographic techniques are commonly used for depositing other layers of device, such as the electrodes.

The cross-point device is a “vertical” device fabricated by depositing each of the components layer by layer. Conventional layer by layer lithography-based fabrication (as in CMOS technology) requires techniques such as layer planarisation. Alternatively, a planar layer of ferroelectric material can be achieved by spin coating the ferroelectric material in solution and then evaporating the solvent, as discussed above. Thus, conventional techniques involve a large number of materials, preparations thereof and deposition steps, and require various different items of fabrication equipment.

### SUMMARY OF THE INVENTION

An object of the present invention is to provide a fabrication route to the production of a passive matrix organic ferroelectric memory array or other cross-point device using inkjet printing to deposit metal or metal like materials, as well as ferroelectric and insulating materials as required. A further object of the present invention is to realise fabrication cost minimisation by fabricating in ambient conditions, and in particular by inkjet printing from solution.

According to a first aspect of the present invention, there is provided a method of manufacturing a cross-point device, comprising:

providing at least one first electrode on a substrate;

providing first regions of an electrically functional material over the at least one first electrode; and

providing at least one second electrode over the at least one first electrode and the plurality of regions of electrically functional material, whereby the first and second electrodes form a plurality of intersections with the electrically functional material between them,

wherein at least two intersections have separate regions of electrically functional material between the first and second electrodes.

Preferably, there are a plurality of both first electrodes and second electrodes and more preferably, each intersection has a separate region of electrically functional material between the first and second electrodes.

In an advantageous embodiment, the invention further comprises, after providing the second electrode:

providing at least one third electrode in a gap between first electrodes or a gap between second electrodes;

providing second regions of electrically functional material over the at least one third electrode and in the gap between the first electrodes and the second electrodes; and

providing at least one fourth electrode over the at least one third electrode and in a gap between the second electrodes or a gap between the first electrodes respectively, whereby the third and fourth electrodes intersect with the second regions of electrically functional material between them,

wherein at least two intersections have separate ones of the second regions of electrically functional material disposed between the third and fourth electrodes. In this way, an interlaced arrangement of the electrodes can be provided.

Again, it is preferred that there are a plurality of third electrodes and fourth electrodes. It is further preferred that, before providing the at least one third electrode:

a region of dielectric material is provided over at least portions of the first and second electrodes that are exposed between the first regions of electrically functional material.

Advantageously, the method may further comprise forming further pairs of intersecting electrode groups with further regions of electrically functional material disposed at the intersections between them, the further pairs of electrode groups being formed in areas over the substrate other than where pairs of intersecting electrode groups have already been formed, and the further regions of electrically functional material being formed in areas over the substrate other than where regions of electrically functional material have already been formed.

It is possible to provide a further region of electrically functional material over both the at least one second electrode and a said first region of electrically functional material; and

provide at least one further electrode over the further region of electrically functional material, whereby said at least one second electrode and the further electrode form an intersection with the further region of electrically functional material between them.

When the electrodes and regions of electrically functional material form an array, the method may further comprise:

providing a passivation layer over the array; and

repeating the steps of the first aspect of the invention on the passivation layer to form a further array.

Further passivation layers and arrays may be provided. Electrodes in at least one array may be at an angle other than parallel with or perpendicular to electrodes in at least one other array.

According to another aspect of the present invention, there is provided a method of manufacturing a cross-point device, comprising:

depositing an electrically functional material on a plurality of first electrodes; and

depositing a plurality second electrodes on the electrically functional material so that the first and second electrodes form a plurality of intersections,

wherein the electrically functional material and the second electrodes are deposited by a printing process.

Preferably, the deposition is carried out by inkjet printing.

According to another aspect of the present invention, there is provided a method of manufacturing a cross-point device, comprising:

depositing an electrically functional material on a first electrode;

depositing a wetting-characteristic layer on the electrically functional material; and

depositing a second electrode on the wetting-characteristic layer, the first and second electrodes intersecting one another.

According to another aspect of the present invention, there is provided a method of manufacturing a cross-point device, comprising:

providing a substrate with at least one first electrode on it;

providing an electrically functional material over the at least one first electrode; and

providing at least one second electrode over the electrically functional material,

wherein the first and second electrodes form at least one intersection with the electrically functionally material between them, and

the first and second electrodes are at an angle other than parallel with or perpendicular to each other.

According to another aspect of the present invention, there is provided a cross point device, comprising:

a plurality of first electrodes;

a plurality of second electrodes intersecting the first electrodes; and

a plurality of regions of electrically functional material between the first and second electrodes,

wherein at least two intersections have separate regions of electrically functional material between the first and second electrodes.

The cross point device may further comprise:

a plurality of third electrodes in gaps between respective ones of the first or second electrodes and electrically isolated from the second or first electrodes;

a plurality of fourth electrodes in gaps between respective ones of the second or first electrodes, electrically isolated from the first or second electrodes and intersecting with the plurality of third electrodes;

a plurality of second regions of electrically functional material at intersections between the third and fourth electrodes and in gaps between the first electrodes, the second electrodes and the first regions of electrically functional material;

wherein at least two intersections have separate second regions of electrically functional material between the third and fourth electrodes.

According to another aspect of the present invention, there is provided a cross point device comprising:

an electrically functional material on a first electrode;

a wetting-characteristic layer on the electrically functional material; and

a second electrode on the wetting-characteristic layer, the first and second electrodes intersecting one another.

According to another aspect of the present invention, there is provided a cross-point device, comprising:

a substrate with at least one first electrode on it;

an electrically functional material over the at least one first electrode; and

at least one second electrode over the electrically functional material,

wherein the first and second electrodes form at least one intersection with the electrically functionally material between them, and

the first and second electrodes are at an angle other than parallel or perpendicular to each other.

By using techniques and ink formulations such as those described herein, single, multiple overlapping, or multiple interlaced cross point arrays can be produced. Such fabrication techniques overcome the cost aspects associated with the evaporation of metals for the cross point electrodes. In addition, the use of inkjet printing as a positive deposition technique allows in situ observation of material deposition. Such a technique is useful in the fabrication of high density structures, whereby alignment may prove very difficult with shadow mask deposition of electrodes. Furthermore, this in-situ observation capability can allow accurate alignment for device fabrication on plastic substrates.

### BRIEF DESCRIPTION OF THE DRAWINGS

Embodiments of the present invention will now be described by way of example only, with reference to the accompanying drawings, in which:

FIGS. 1a and 1b are schematic representations of ferroelectric cross point devices;

FIG. 2a is a schematic representation of a cross point structure fabricated using conventional CMOS type techniques.

FIG. 2b is a schematic representation of a cross point structure fabricated according to the present invention;

FIG. 3 is a schematic representation of the architecture of a cross point device structure according to the present invention;

FIGS. 4a-e show a method of fabricating a further cross point device structure according to the present invention;

FIGS. 5a and b show a method of fabricating a further cross point device structure according to the present invention;

FIG. 6 is schematic cross sectional view of a further cross point device structure of the present invention;

FIG. 7 is a schematic representation of the architecture of a further cross point device structure according to the present invention;

FIGS. 8a-i show a further method of fabricating a cross point device structure according to the present invention; and

FIGS. 9a-y show a yet further method of fabricating a cross point device structure according to the present invention.

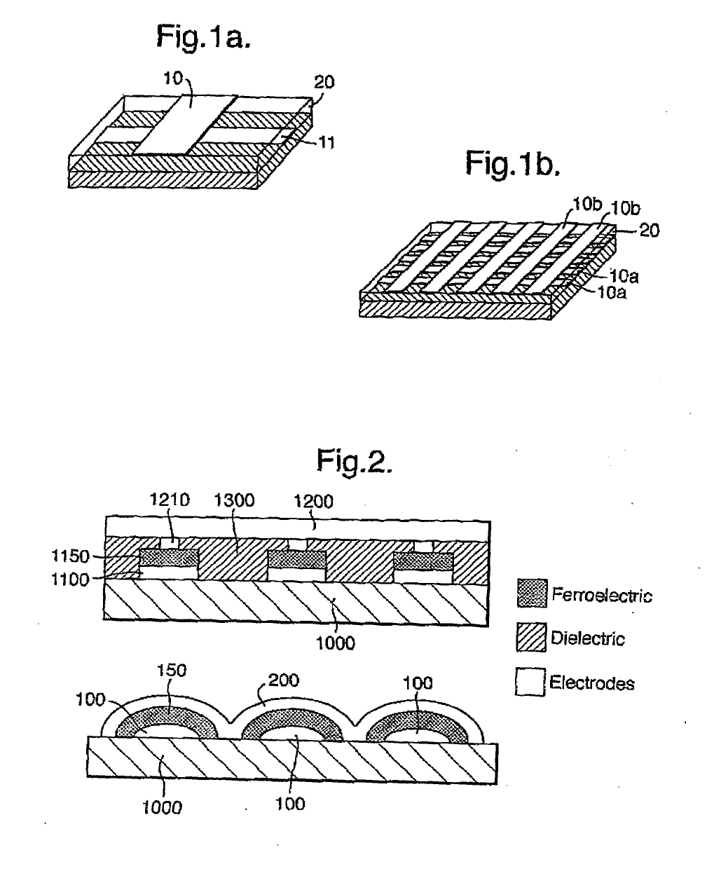

### DETAILED DESCRIPTION

In this specification, the term “electrically functional material” is intended to refer to the material in the cross point device that provides the desired electrical effect—that is, the ferroelectric material, the light emitting material, the capacitive material, the semiconductor material and so on. However, it may also refer to the electrodes or other material having desirable electrical properties.

In one aspect of the present invention, a cross point device such as a ferroelectric memory device can be fabricated entirely using inkjet deposition techniques, or at least using inkjet techniques for printing the electrically functional material (such as the ferroelectric material) and the top electrodes. In particular, unlike the prior art, in this aspect of the invention inkjet printing may be used to pattern the electronically functional materials. Moreover, no planarisation is required during fabrication, whether by spin coating or other techniques.

Thus, by comparison to conventional layer by layer lithography-based fabrication techniques (as in CMOS technology), the inkjet printing fabrication method of the present invention overcomes the need for techniques such as layer planarisation. This reduces the number of materials and preparations thereof, as well as the number of deposition steps.

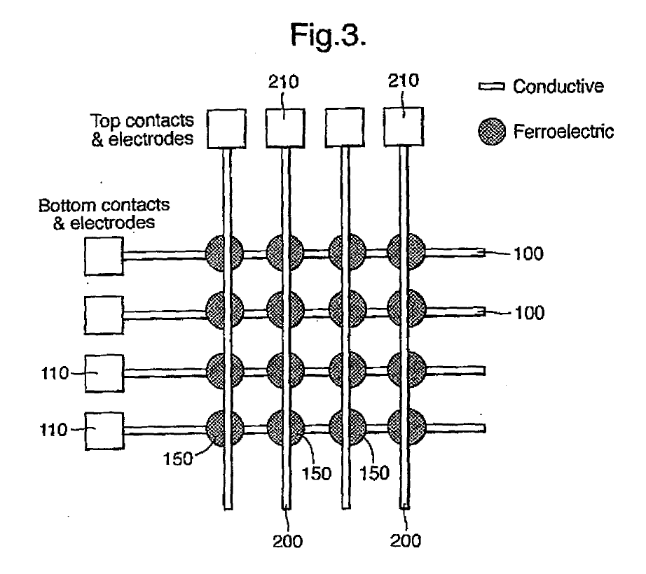

The fundamental structure of a cross point array realised by inkjet printing in accordance with the present invention is shown in plan view in FIG. 3. Briefly, the cross point array in FIG. 3 comprises a plurality of bottom electrodes 100 disposed on a substrate 1000. Each of the bottom electrodes is connected to a respective pad 110 provided on the substrate 1000. A region of ferroelectric material 150 is provided at intervals on each of the bottom electrodes 100. A plurality of top electrodes 200 is disposed at right angles to the bottom electrodes 100, so that each of the regions of ferroelectric material 150 is disposed at the intersection of and between a bottom and top electrode.

The fabrication process in order to realise such a device via inkjet printing will now be described. Firstly, the bottom electrode 100 can be formed by a “free format” inkjet printing process that essentially uses the native contact angle of a liquid droplet on a surface of the substrate or material provided on the substrate 1000 to define the track width dimension. The track width is inversely proportional to the contact angle exhibited by the printed material on the surface. The free format technique is extremely useful as no pre-patterning is required to define the inkjet printed track, and is intrinsically applicable to multiple layer structures as a film can be simply coated on a device and inkjet printed directly. The need for layer to layer pre-patterning alignment (as is the case for photolithography) is circumvented by this process.

Depending on the wettability of the substrate with respect to the solution used to inkjet print the bottom electrode, it may not be possible to define the bottom electrode on a substrate surface as required by directly printing on the substrate surface itself. Often, it is necessary to cover the substrate surface with a surface “wetting” layer in order to control the wetting property of the inkjet printed tracks. It should be noted that the term “wetting layer” is intended in this specification to mean a layer that adjusts wettability and thus to include both layers that increase and layers that decrease wettability. Taking an aqueous based conducting material such as PEDOT:PSS as an example, and a substrate such as glass, or poly(ethylene naphthalate) (PEN) or poly(ethylene terephthalate) (PET), then a variable wetting of the printable conductor may occur on the surface. By using a thin film of a hydrophilic substance such as PVP, the wetting can be uniformly achieved from a spin-coated film. Alternatively, the wetting material can be inkjet printed on the substrate where required. The printed tracks can then be achieved with a high regularity. This can be achieved for any water based conducting material. Of course, where the wettability of the substrate with respect to the solution is acceptable, there may be no need to provide a wetting layer.

The contact pads 110 as shown in FIG. 3 may be inkjet printed or may be pre-patterned contacts from a previous process such as metal evaporation.

After the deposition of the bottom electrodes 100, a drying or annealing step may be required to remove any residual solvents from the tracks, or to aid the increase in the track conductivity. The temperatures used in the process will vary according to the material. Typically, for inkjet printing on flexible substrates an upper temperature of 150° C. is acceptable.

After the annealing step of the electrodes, the ferroelectric layer 150 (in the form of a number of distinct regions) is deposited. Taking the example of a polymer ferroelectric P(VDF-TrFE), this can be inkjet printed from a number of solvents. Apart from a high solubility in a solvent, the boiling point (thus solvent vapour pressure) is an important parameter in the selection of a solvent for inkjet printing. Prime solvents for printing the P(VDF-TrFE) for such a process are 1,3-dimethyl-2-imidazolidinone (DMI) and 1-methyl-2-pyrrolidinone (NMP) due to their boiling points of 225° C. and 202° C. respectively. Other solvents such as cyclohexenone (boiling point 168° C.), 1-acetyl-1-cyclohexene (boiling point 201° C.) and benzyl acetone (boiling point 235° C.) may also be suitable candidates. Preferably, each ferroelectric region 150 is formed of one droplet of inkjet deposited material.

After deposition of the ferroelectric material, it may be necessary to remove the residual solvent. The solvents used for inkjet printing may have higher drying temperatures than normal and longer intervals during printing may be needed. Although some drying will occur at the inkjet printer, further removal of the host solvent by heating may be required to ensure a dry film is achieved. This can be achieved by heating the sample on a hotplate (for a film cast from 2-butanone, heating at 60° C. for 20 minutes is sufficient). In addition, the sample can be annealed in order to increase the ferroelectric response of the material by a crystallisation process of the material. Annealing at 140° C. for 1 hour is sufficient to attain this increase in the ordering of the material.

Next, the top electrodes 200 are deposited. However, as described earlier, the contact angle of an aqueous borne conductor will exhibit a high contact angle on a native P(VDF-TrFE) surface. A PVP wetting layer (again in the order of 10nm in thickness) can be inkjet printed or spin coated. The solvent for casting the PVP layer by spin coating can be ethanol or isopropanol. For inkjet printing a respective PVP region on each electrically functional region, a solvent with a lower vapour pressure is required. A solvent such as benzyl alcohol (boiling point 205° C.) can be used for producing a printable ink.

The top electrodes 200 can be deposited on the discrete ferroelectric/wetting layer stack as the PVP wetting layer is continuous over each region of the ferroelectric layer (and the substrate surface when deposited by spin coating), thus completing the ferroelectric capacitor structure.

As an alternative, a surface tension reducing agent such as a Triton-X surfactant may be added to the water based solution in order to reduce the contact angle with a hydrophobic surface.

A comparison of a simple cross point array of the present invention that could be fabricated by conventional CMOS type methods (a) and by inkjet printing as in the present invention (b) is shown in FIG. 2. In FIG. 2(a) the multi-layered nature of the device structure is shown, whereby the bottom electrodes 1100 are deposited on the substrate 1000 and then patterned by lift-off techniques or etching. Similar techniques are employed for the ferroelectric layer 1150 (in this case an inorganic ceramic would be used). In addition to the patterning steps, a dielectric layer 1300 is required for successful deposition of the top electrodes 1200. The dielectric layer 1300 (typically a material such as silicon dioxide) also has to be planarised by chemical mechanical polishing in order to achieve a sufficiently smooth arid level surface before the top electrodes 1200 can be deposited. In addition, patterning of a via connection 1210 to the ferroelectric 1150 may also be required. Such fabrication methods lead to a purely vertical structure, with each layer of material vertically segmented from another. The limitations of this type of fabrication, and the requirements for subsequent layers can be inhibitive to desired structures, and costly to manufacture.

The device structure shown in FIG. 2(b) is a cross point array to realise the same functionality as in (a). As can be seen, the need for planarising the structure is not required, as the top electrode 200 (which runs from left to right) is at the same vertical level as the bottom electrodes 100 (which run into the plane of the page) at intermediate positions of the cross points, hence the “lateral” layered device as mentioned earlier. Such a device fabrication means that a multi-layered device in the conventional sense can be made laterally if required. This patterning technique means that different functional devices can be made on the same level of the substrate if desired, rather than having to adhere to strict fabrication steps (and associated requirements) for multiple layered devices.

The integration and interconnections can be made at any time because different functional materials can be printed in any desired sequence and position. This fabrication route is more flexible than that in conventional CMOS type fabrication routes, whereby only one material can be deposited at any one vertical level in the device.

In order to increase the density of a printed cross point array, a multiple array, laterally stacked structure can be fabricated. This may be desirable when the lateral dimension of the printed ferroelectric material regions 150 is larger than the lateral pitch of the bottom electrodes 100. Rather than making two cross points over one printed droplet of the ferroelectric, a second cross point array can be made over the first array in an interlaced configuration. Due to a drying phenomenon called the “coffee stain” effect, the profile of a printed droplet does not exhibit a constant thickness. Therefore, if two cross points are fabricated using one printed droplet of ferroelectric material, then the two may not have the same characteristics due to the difference in thickness in the ferroelectric layer. An interlaced structure incorporating one printed droplet per cross point can overcome such problems. The interlaced structure allows the maximum resolution to be achieved by inkjet printing.

The lateral structure achieved by the present invention allows further pairs of first and second electrodes, with ferroelectric material between them at the intersections, to be deposited without first performing any planarisation step, and even without providing a passivation layer across the whole device structure. In particular, the present invention provides a structure in which a first sub-array is formed by a plurality of first electrodes, a plurality of second electrodes at right angles to the first electrodes so that the first and second electrodes intersect, and a distinct region of ferroelectric material between each the first and second electrodes at each intersection. Such a sub-array is similar to the array shown in FIG. 3. A second sub-array of the device is then provided without planarisation. Specifically, the second sub-array is provided not directly over the first layer, but instead in the gaps between the first electrodes, the second electrodes and the regions of ferroelectric material in the first sub-array. Third and further sub-arrays can then be deposited in the remaining gaps, if desired, again without any planarisation. In this way, a “lateral” device structure is achieved in which different sub-arrays and different layers within the sub-arrays can be at the same distance from the substrate.

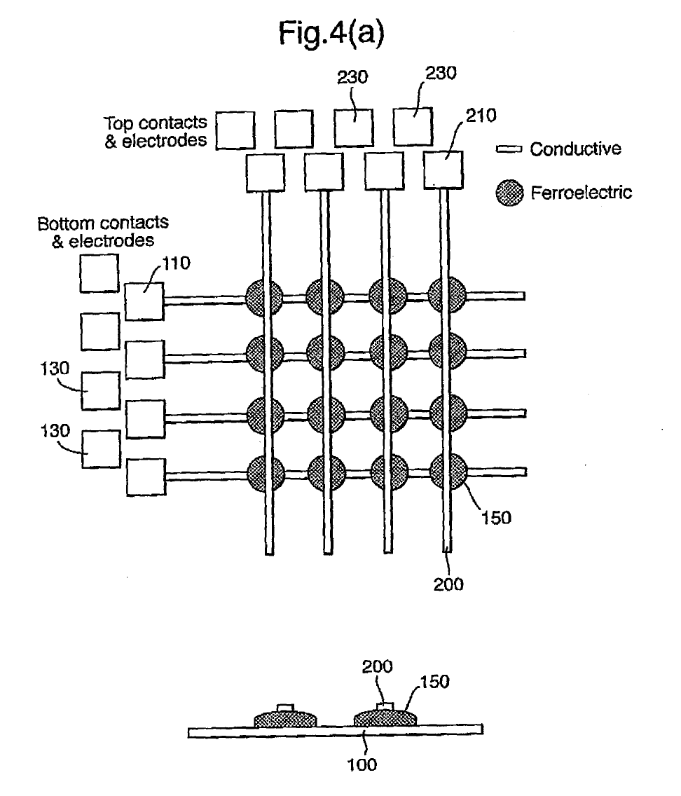

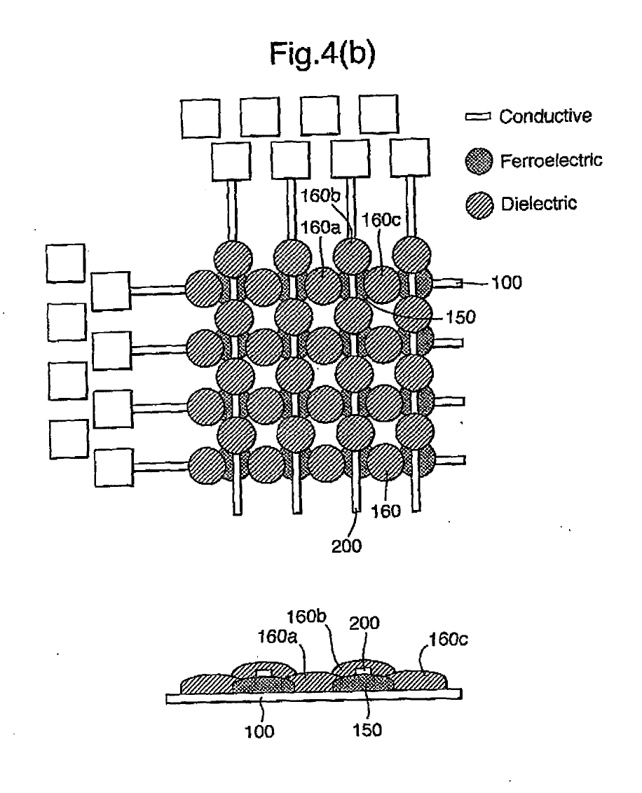

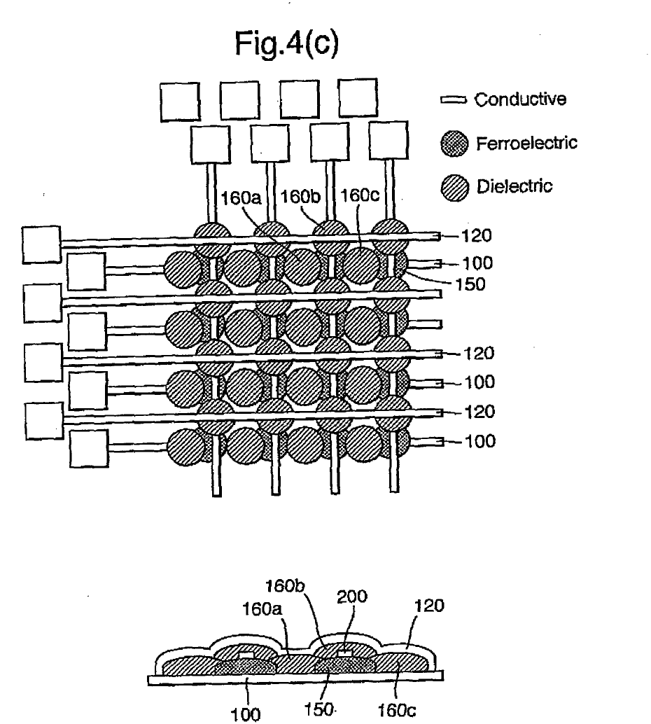

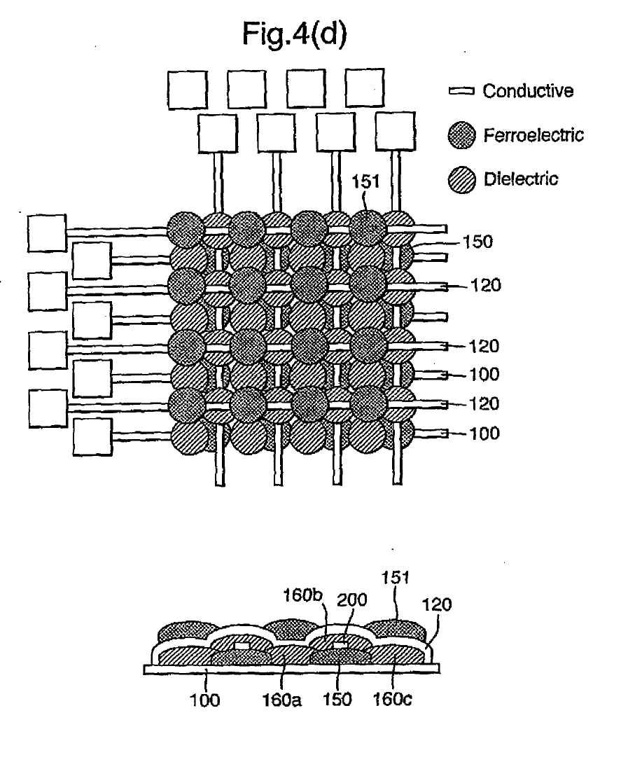

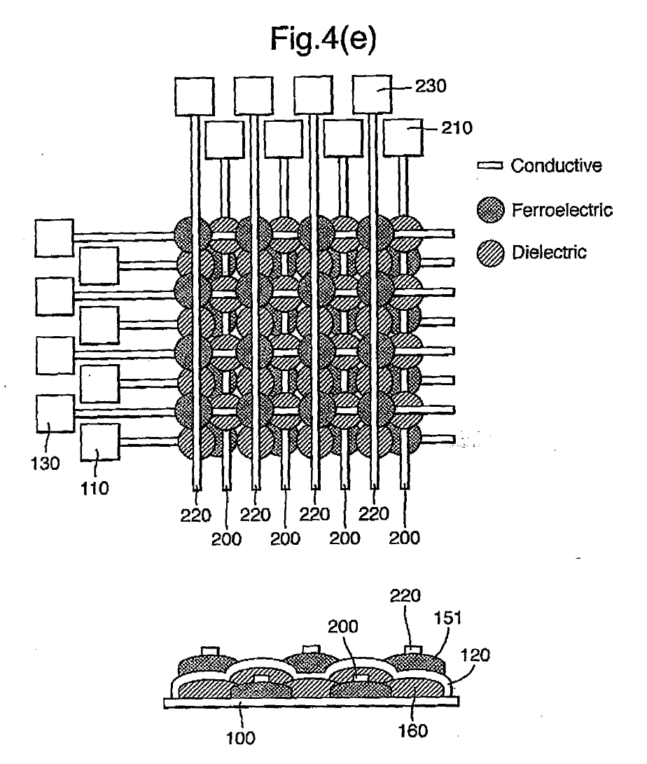

FIG. 4 shows the fabrication of such an interlaced cross point structure, comprising two sub-arrays. FIG. 4(a) shows in plan view the single cross point array as in FIG. 3, but with an additional set of top and bottom contacts 130, 230 at intermediate positions to the array. FIG. 4(a) also shows a schematic cross-section of a portion of the plan view. Specifically, it shows the droplet of ferroelectric material 150 between a bottom electrode 100 and a top electrode 200.

In order to fabricate bottom electrodes 120 for the second sub-array, dielectric material 160 is deposited on top of the remaining exposed areas of electrodes 100, 200 first sub-array, as shown in FIG. 4(b). The schematic cross-section in FIG. 4(b) shows how two droplets of dielectric 160a, 160c to the left and right of a droplet of ferroelectric material 150 are at the same level as the droplet of ferroelectric material 150. Conversely, since they are deposited on the top electrode 200, two droplets of dielectric 160b, 160d above and below a droplet of ferroelectric material 150 in the plan view are, at least in part, higher than the droplet of ferroelectric material 150.

The selection for this dielectric may be from a number of materials. Some examples include poly(vinyl phenol), poly(methyl methacrylate), polystyrene, polyisobutylene, polyimide and benzocylobutene. All of the examples given are soluble in (or processible from) inkjet printable solvents. Solvents such as alcohols, ketones and polar and non-polar organic solvents (but not all for one material) may be used to produce inkjet printable solutions. Preferably, the dielectric 160 is deposited by inkjet printing. However, it is also possible to cast a dielectric film by spin coating. It should also be noted that although the figure shows all exposed portions of the top and bottom electrodes being covered by the dielectric, it is only necessary to cover those exposed portions of the first and second electrodes on which further electrodes are to be printed.

Once the dielectric 160 has been deposited and dried, the bottom electrode 120 for the next array can be printed as shown in FIG. 4(c). Again, as with depositing an electrode on the ferroelectric layer 150, a wetting layer may be required on top of the dielectric 160 depending on the choice of material, for example from the list highlighted earlier. For example, the poly(methyl methacrylate), poly(isobutylene) and polystyrene dielectrics offer a rather poor wetting capability for an aqueous based conducting material. In this case, as previously mentioned, a hydrophilic layer will be required in addition to the dielectric. However, these non-polar dielectric materials will show a strong wetting ability for a non-polar organic solvent based conducting material, and therefore a wetting layer may not be required when they are used. Again, it is preferred that any necessary wetting material be deposited in the required places by inkjet printing. However, a wetting layer may also be cast by spin coating.

Second regions of ferroelectric material 151 can be deposited in the positions shown in FIG. 4(d), and again, a wetting layer may be required before printing of the top electrodes 220 shown in FIG. 4(e), thus completing a lateral, interlaced double-stacked cross point array. This lateral, interlaced double-stacked cross point array comprises a first sub-array (bottom electrode 100, ferroelectric 150, top electrode 200) interlaced with a second sub-array (bottom electrode 120, ferroelectric 151, top electrode 220), at least some portions of which are on the same vertical level.

If the pitch of the electrodes 100, 120, 200, 220 and the size of the ferroelectric regions 150, 170 and the dielectric regions 160 allow, third and further sub-arrays may be stacked to form a high density lateral, interlaced arrangement.

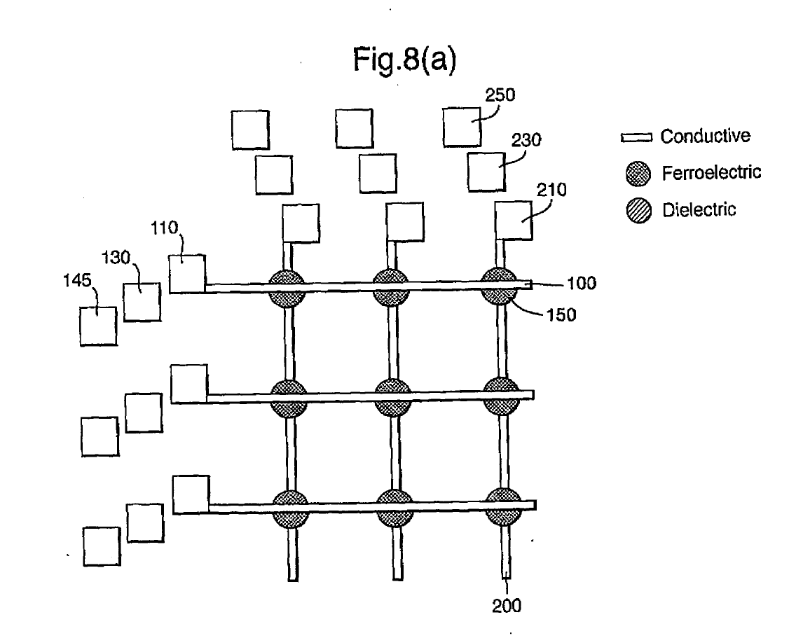

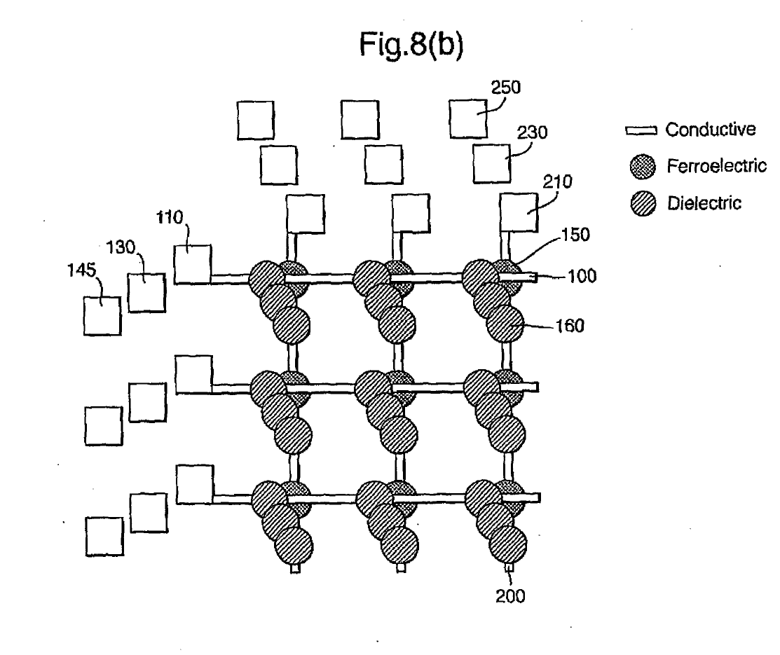

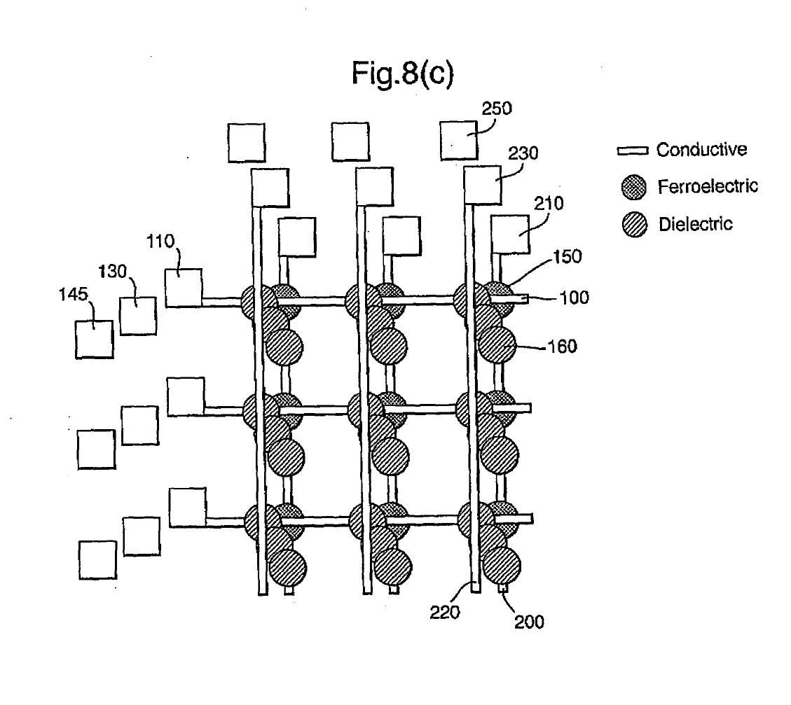

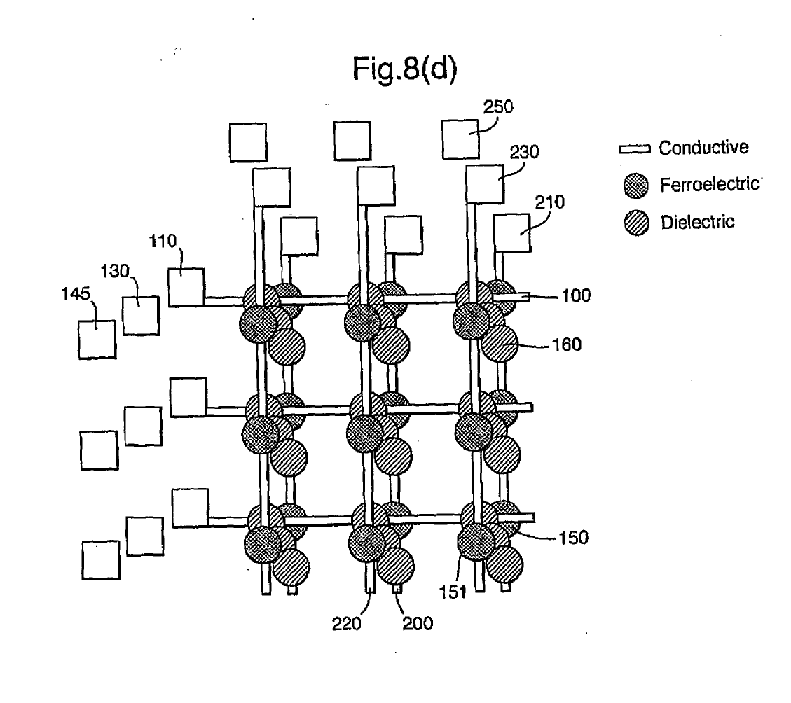

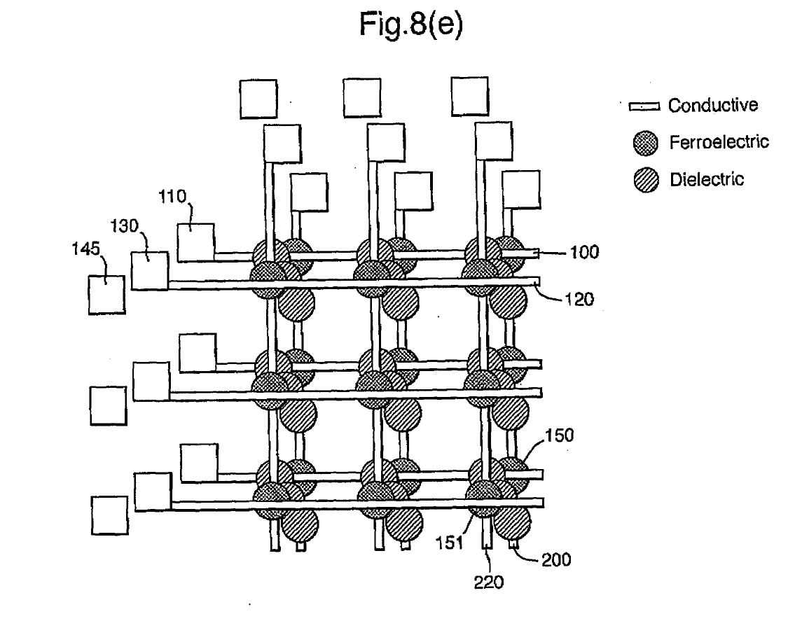

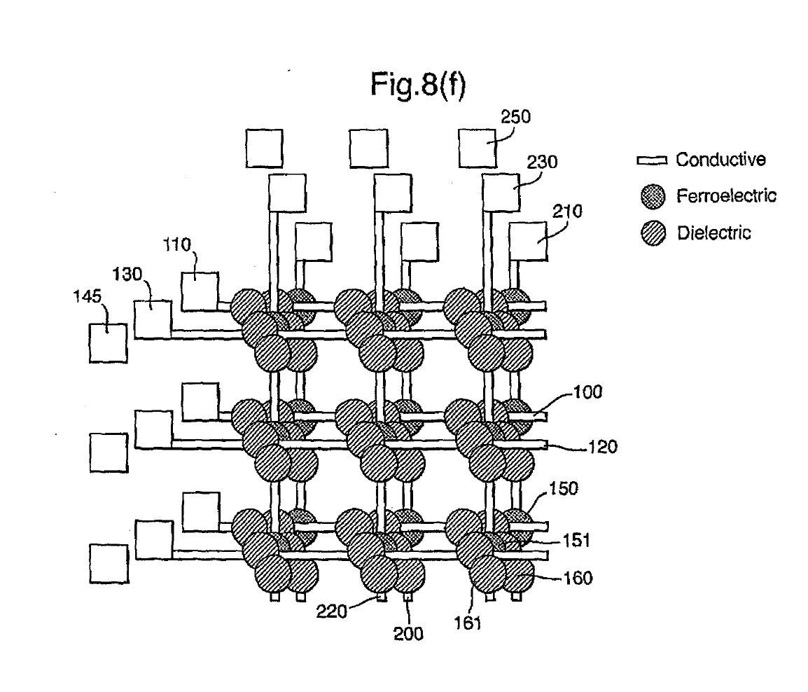

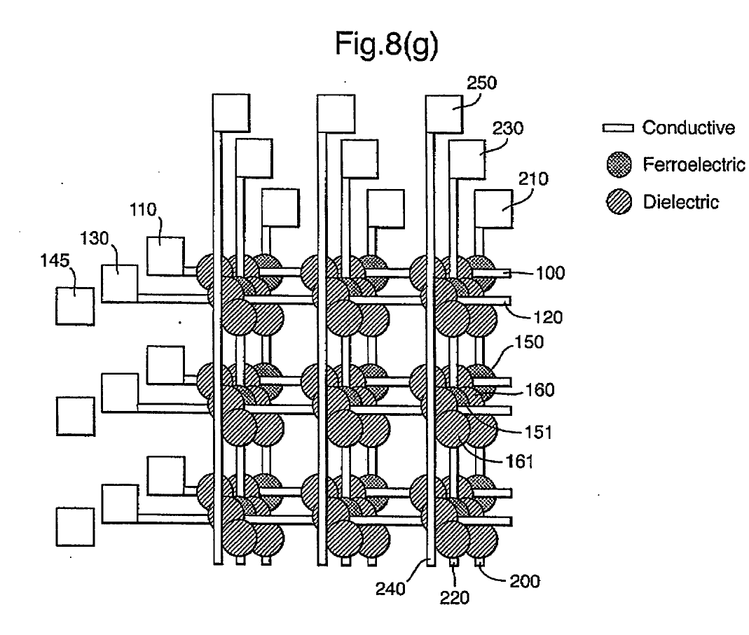

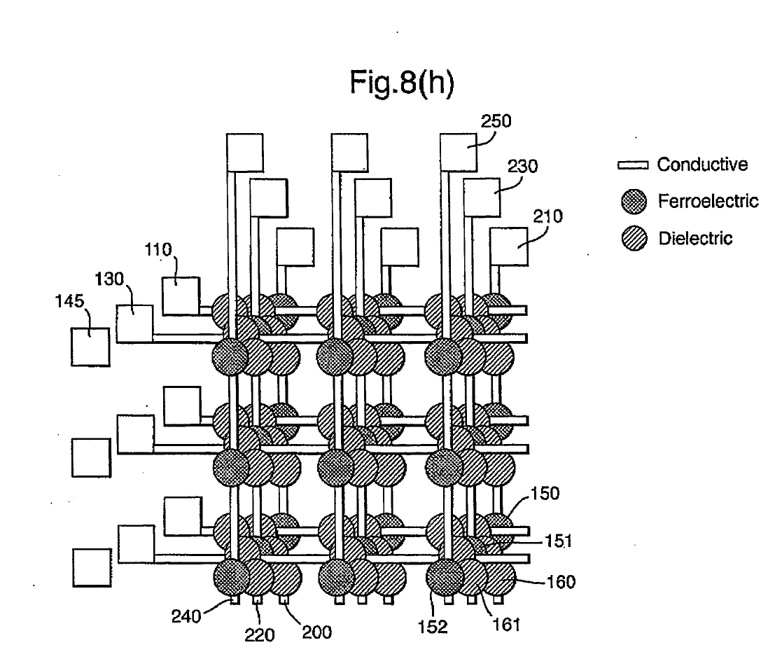

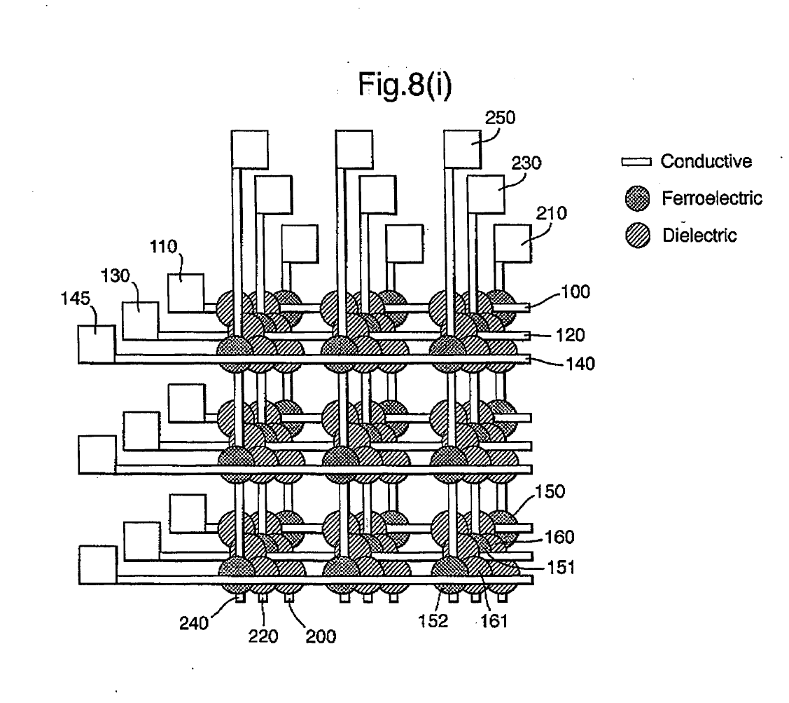

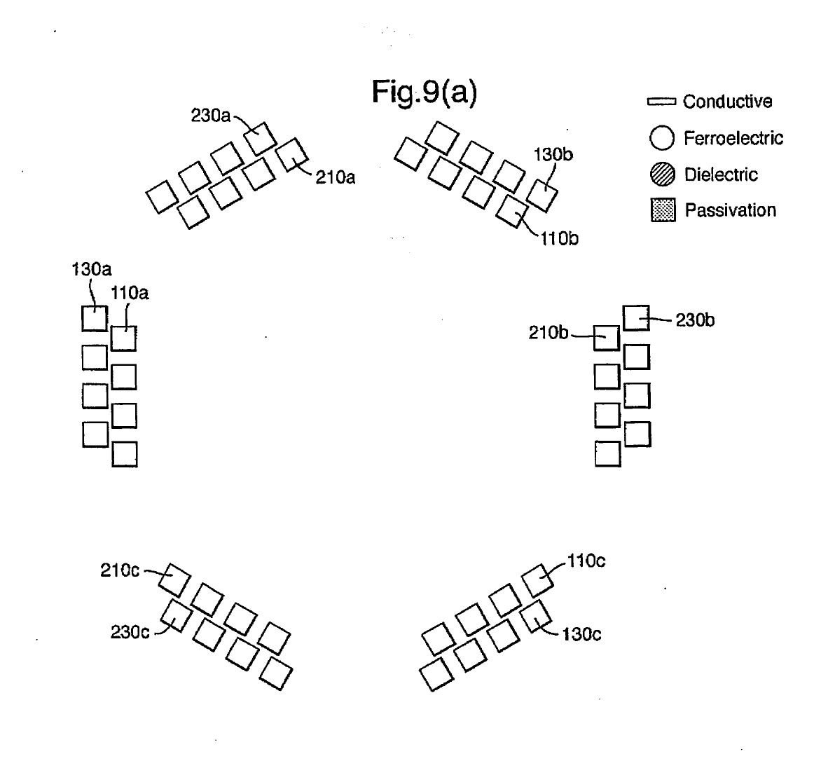

An example of the formation of a lateral, interlaced triple-stacked cross point array comprising three sub-arrays is shown in FIGS. 8(a)-(i). FIG. 8(a) is similar to FIG. 4(a) in that includes bottom and top electrode contact pads 110, 130, 210, 230 for first and second sub-arrays, although in this case the bottom electrodes 200 run from top to bottom on the page and the top electrodes 100 run from left to right on the page. In addition, however, FIG. 8(a) includes contact pads 145, 250 for a third sub-array.

In FIG. 8(b), a dielectric 160 is deposited as a series of three droplets to insulate the first sub-array from the second sub-array. In this example, three droplets are deposited in a line. Of course, a short track of dielectric could be printed, or a different number of droplets could be deposited, or a different pattern could be used, or the dielectric could be deposited by spin coating.

FIG. 8(c) shows the bottom electrodes 220 of the second sub-array parallel to the bottom electrodes 200 of the first sub-array. It is worth noting, however, that as with other examples the bottom electrodes 220 of the second sub-array could be provided parallel to the top electrodes 100 of the first sub-array.

FIG. 8(d) shows second droplets of ferroelectric 151 being deposited; FIG. 8(e) shows the top electrodes 120 of the second sub-array being deposited and connected to contact pads 130; FIG. 8(f) shows dielectric 161 being deposited in the same way as the dielectric 160, in order to separate the second and third sub-arrays; and FIGS. 8(g)-(i) shows the third sub-array being deposited, with bottom electrodes 240, ferroelectric 152 and top electrodes 140.

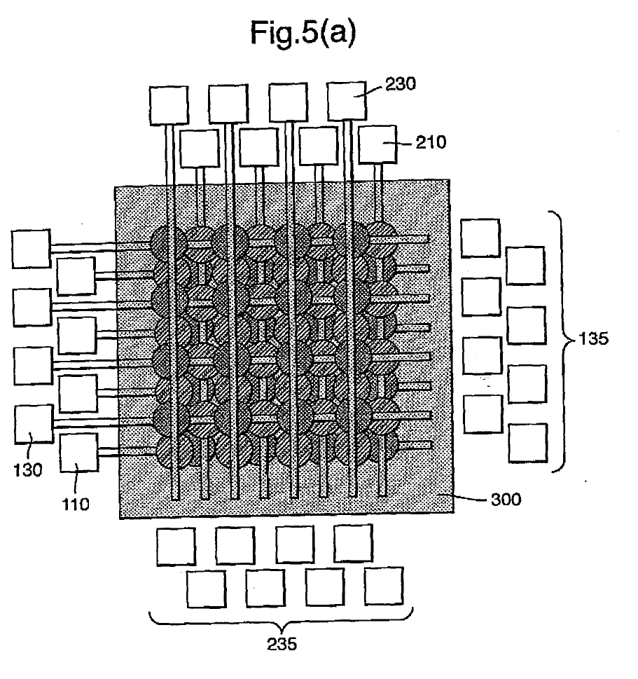

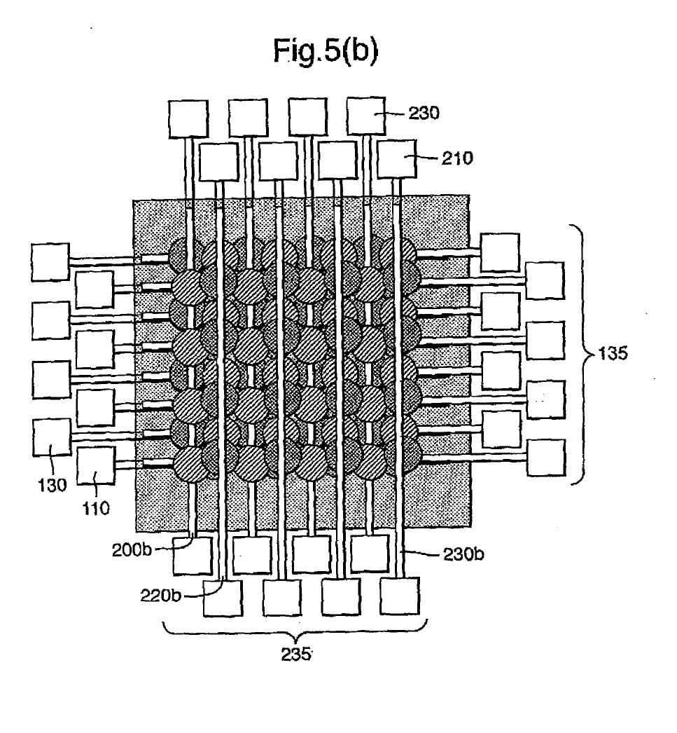

Once the single cross point array structure or the double (or more)-stacked, interlaced cross point array structure is complete, further cross points may be added by depositing a passivation film and repeating the process. Such an example is shown in FIG. 5. In particular, FIG. 5 shows additional groups of contact pads 135, 235 provided on the substrate 1000 for a further double-stacked lateral, interlaced cross point array to be formed on one similar to that illustrated in FIG. 4. The additional groups of contact pads 135, 235 are provided on opposite sides of the array to the groups of contact pads 110, 130, 210, 230 used for the first array.

After the lateral, interlaced cross point array of FIG. 4 is completed, a passivation layer 300 is provided, as shown in FIG. 5(a). Such passivation reduces any surface undulations in the device topography induced by the numerous layers of the inkjet printed materials, and ensures electrical isolation from the underlying cross point array. Such a film 300 may be deposited by inkjet printing or spin coating if desired. Since the array is a large structure compared with the individual cross points in the device, and since the groups of contact pads are offset from the array, the degree of accuracy required to deposit the passivation film is comparatively low. Consequently, such techniques do not present significant difficulties or have significant cost implications.

Subsequently, as shown in FIG. 5(b), the further lateral, interlaced cross point array with bottom and top electrodes connected to the pad groups 135, 235 respectively can be deposited in the same way as initially illustrated in FIG. 4.

This process of depositing a passivation film and fabricating a further array can be repeated as required in order to create the memory size required. Such a procedure is efficient in order to reduce the lateral size of a memory chip. The example of the device fabrication shown here for an interlaced array may be implemented for an overlapping cross point arrays geometry, and any other positions or angles subtended between the arrays.

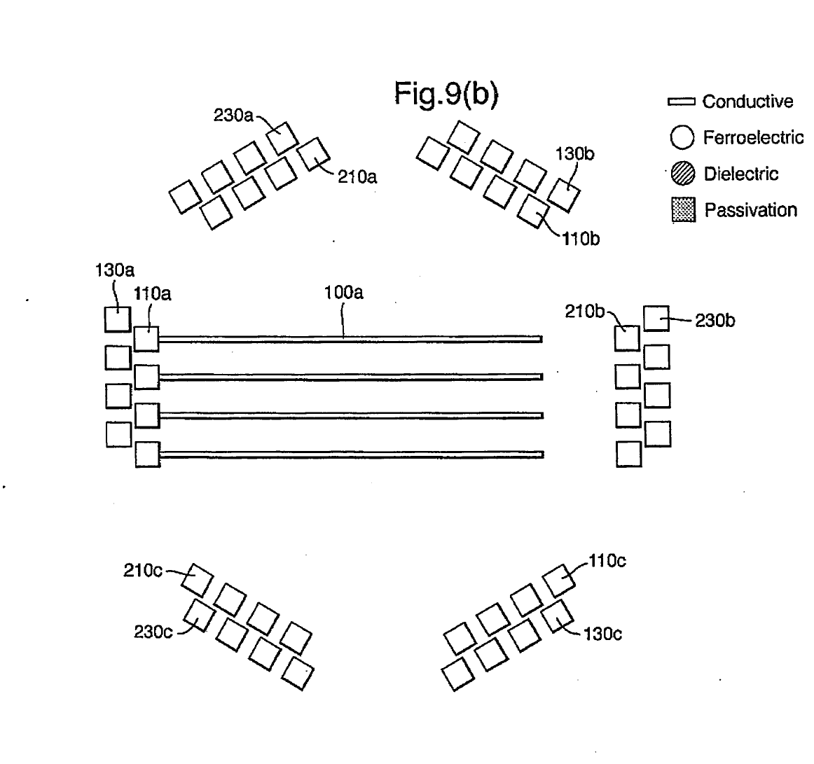

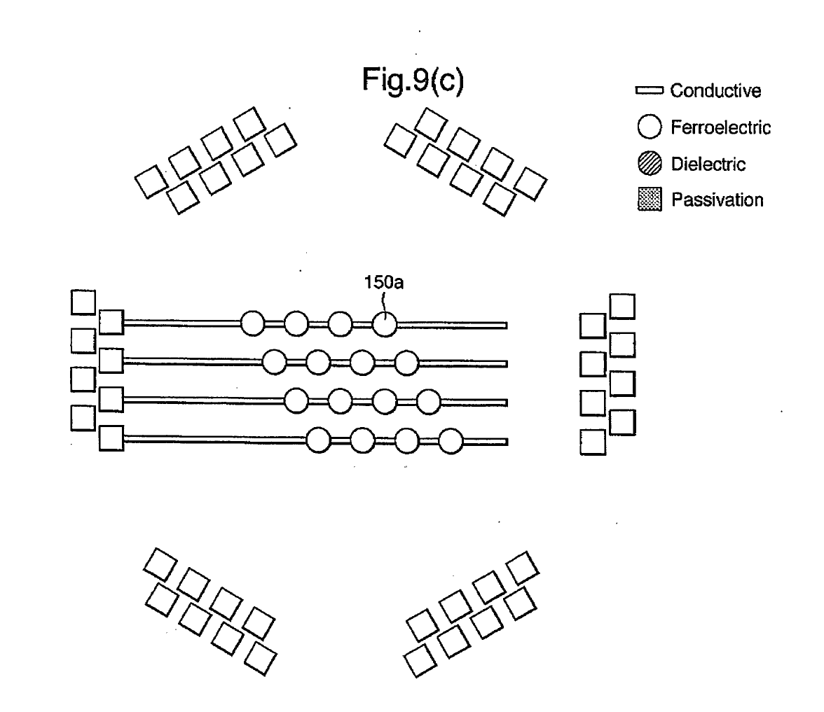

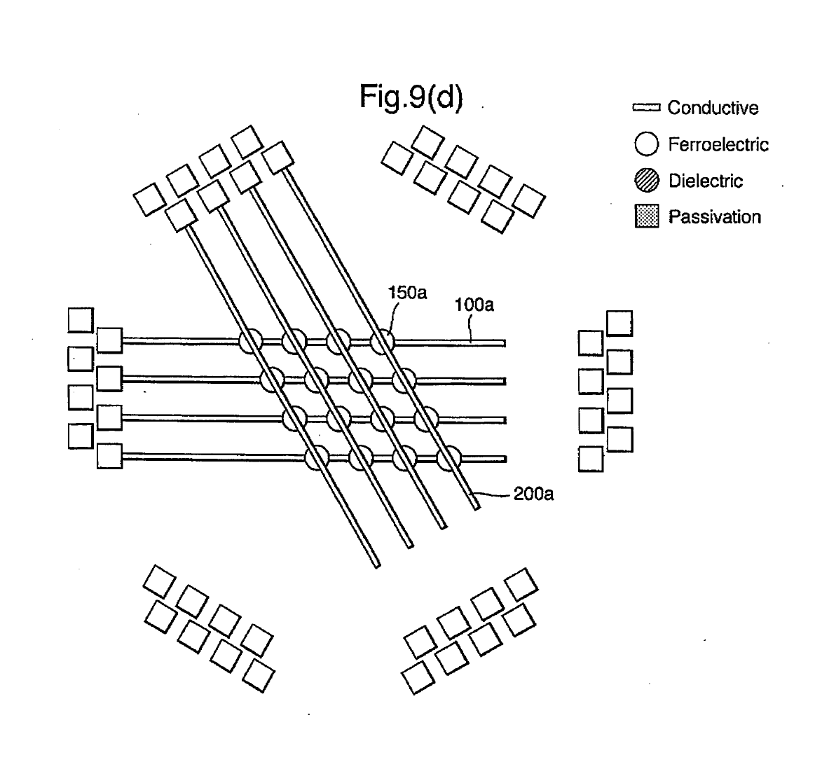

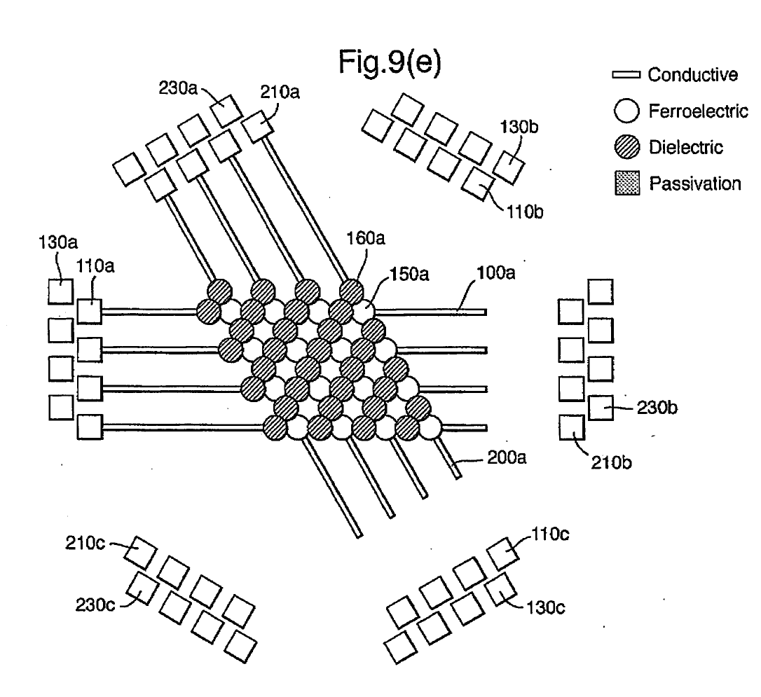

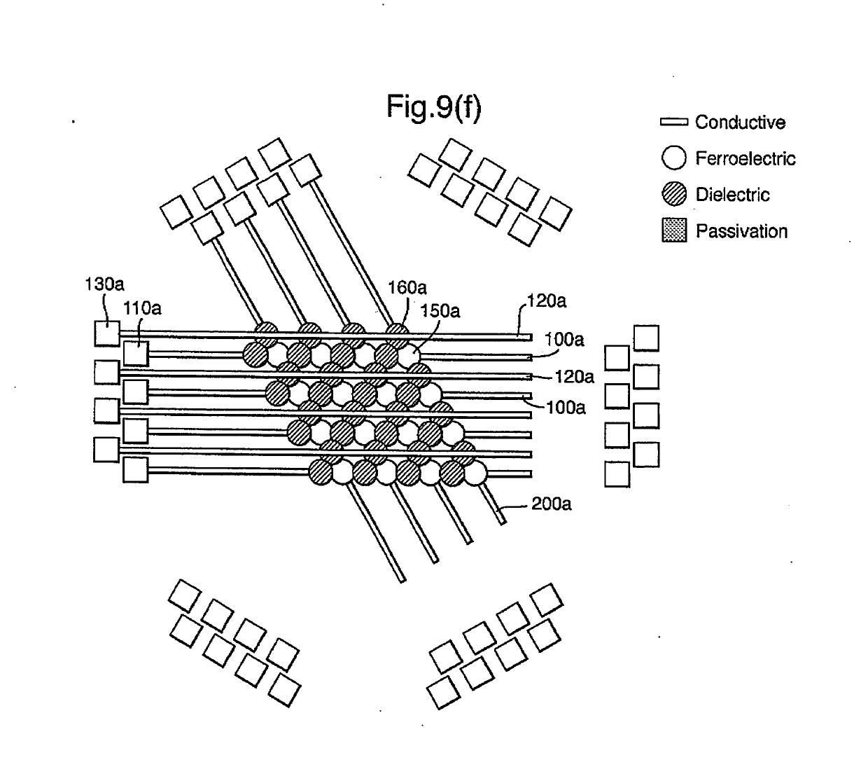

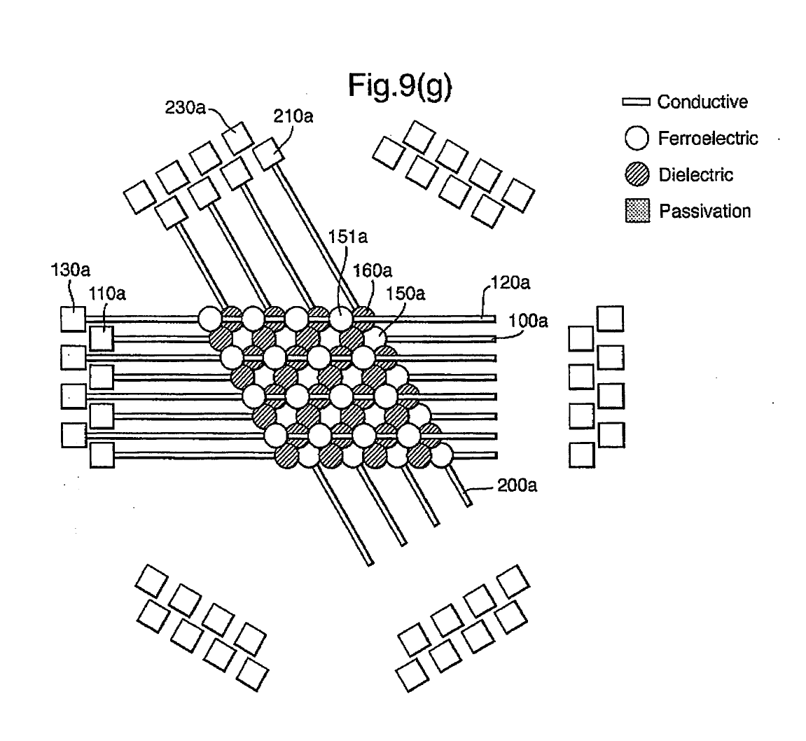

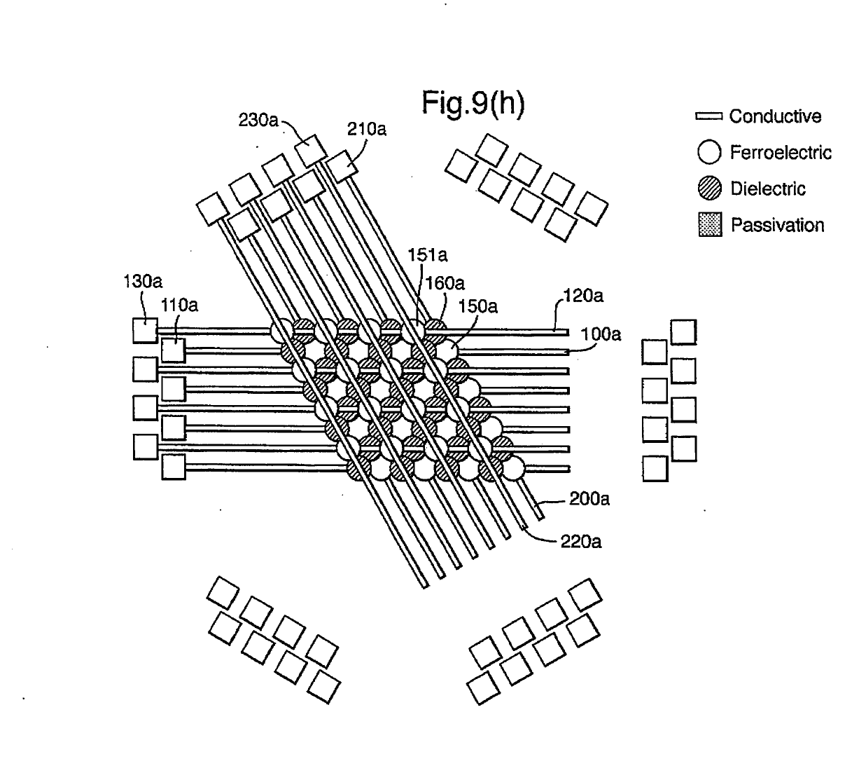

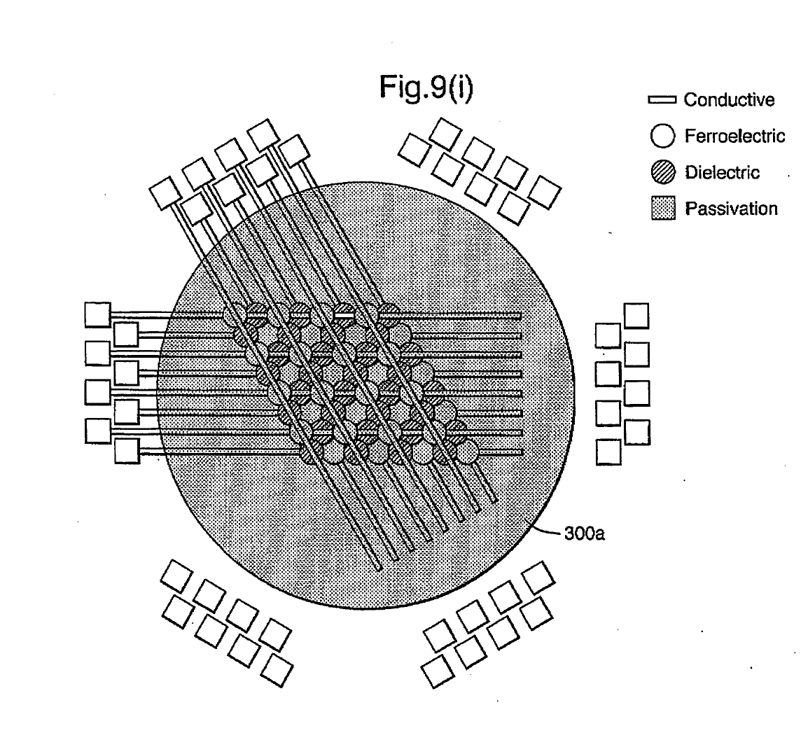

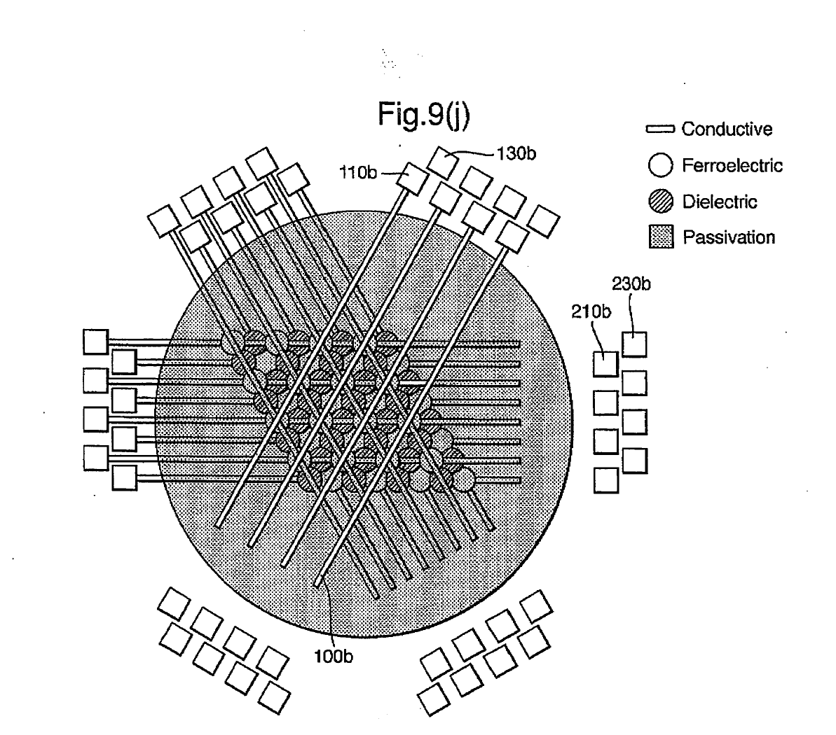

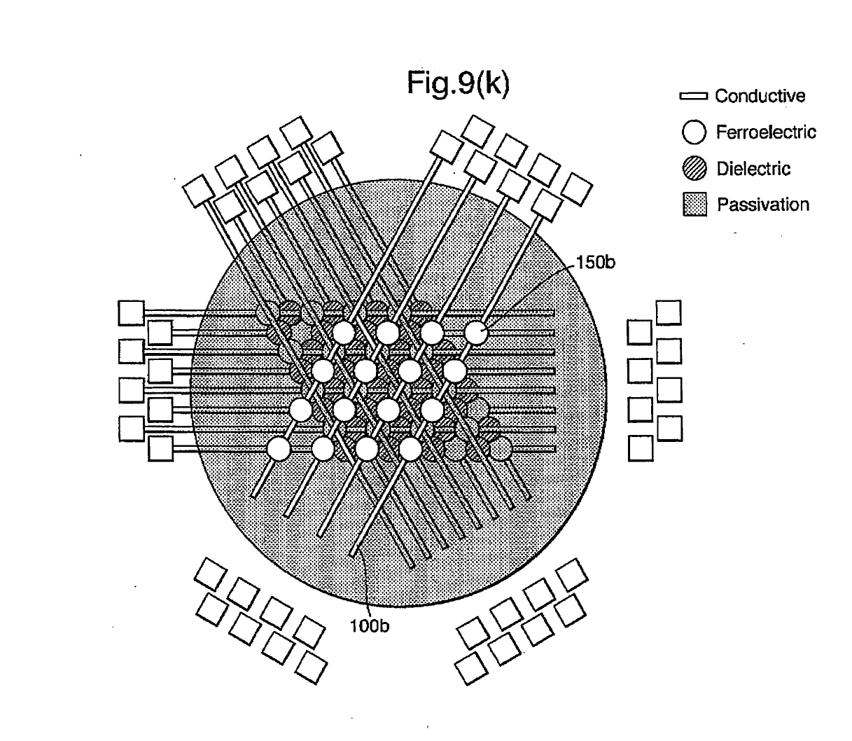

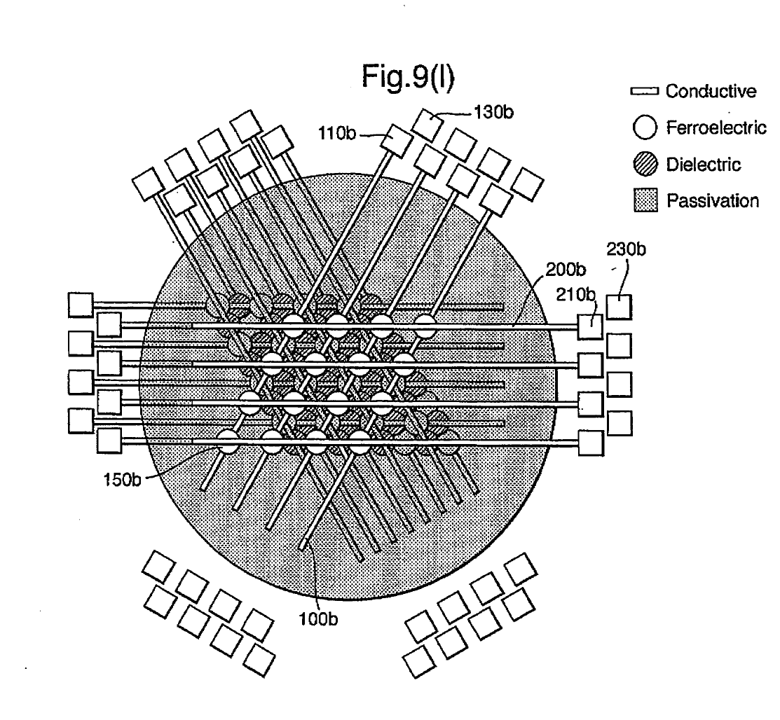

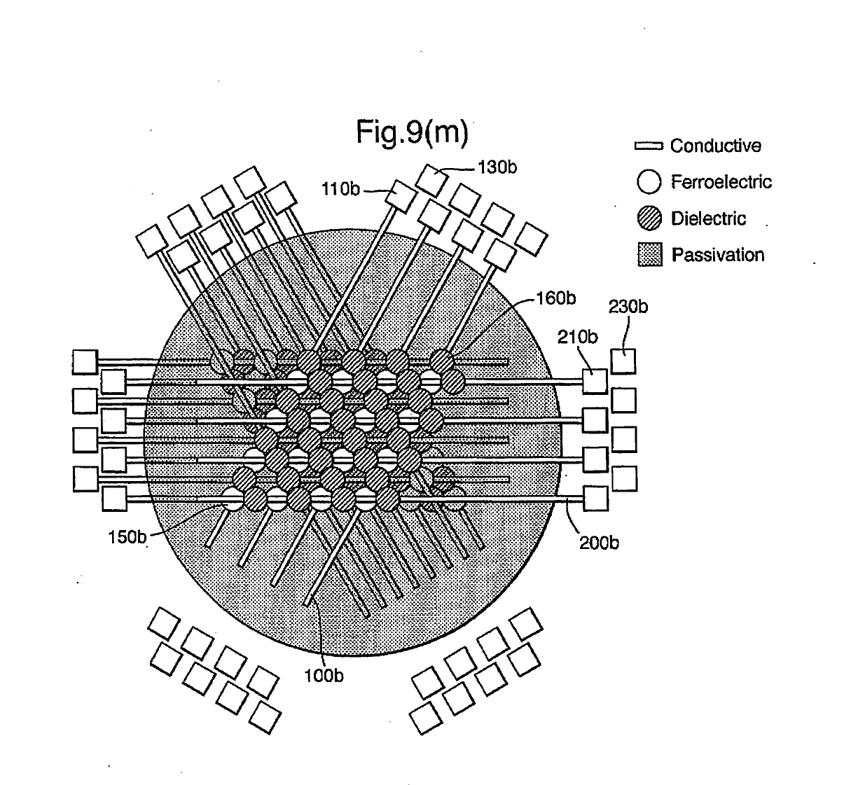

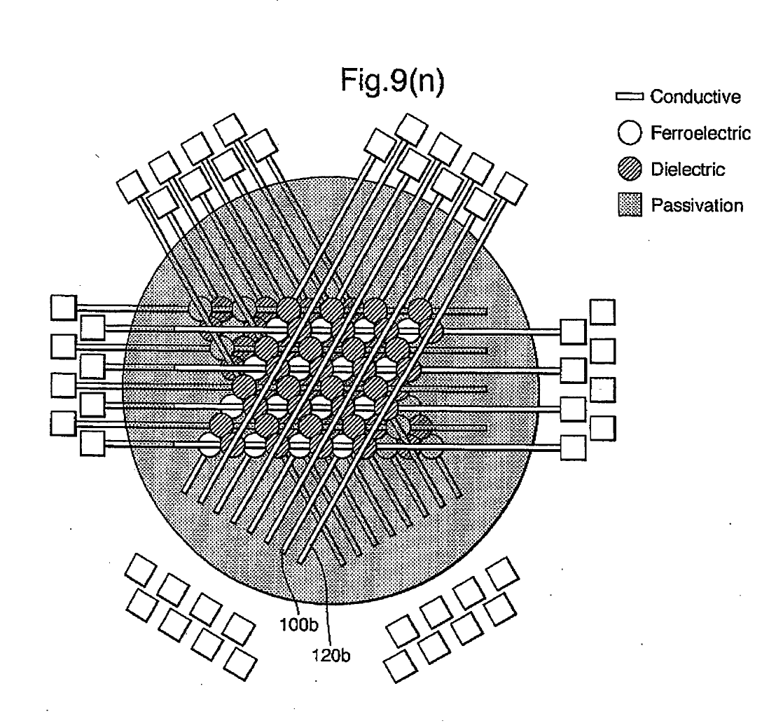

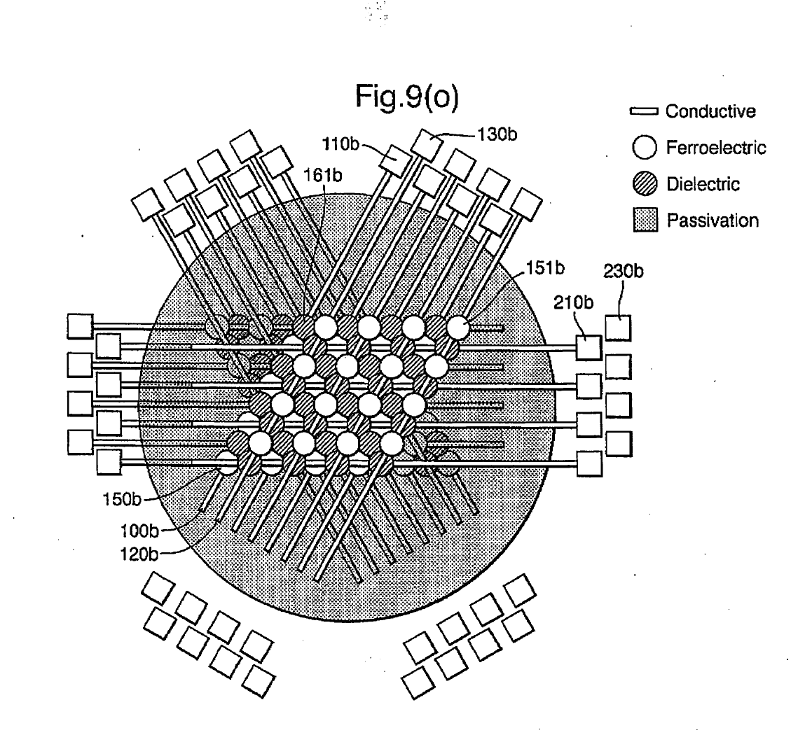

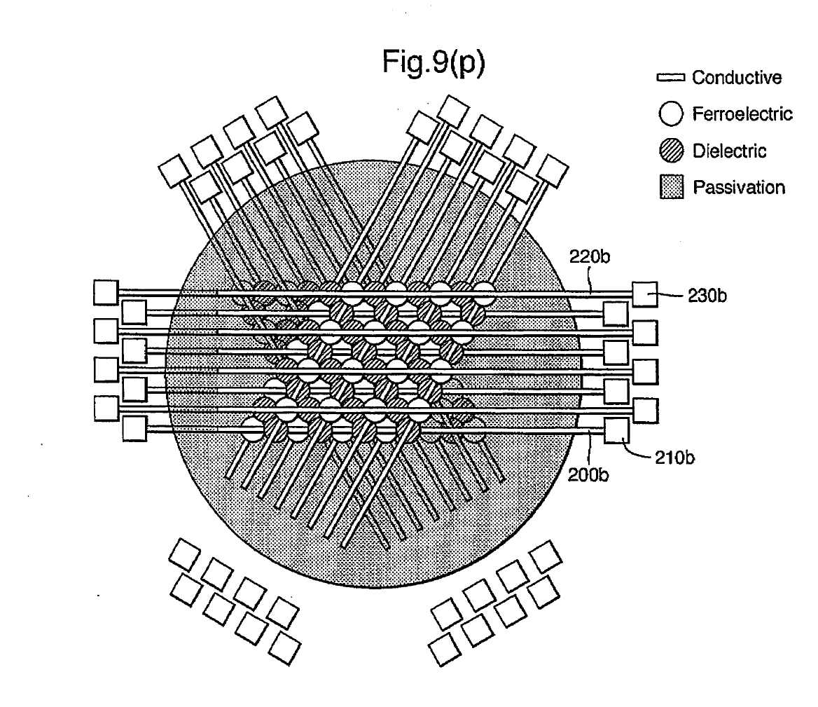

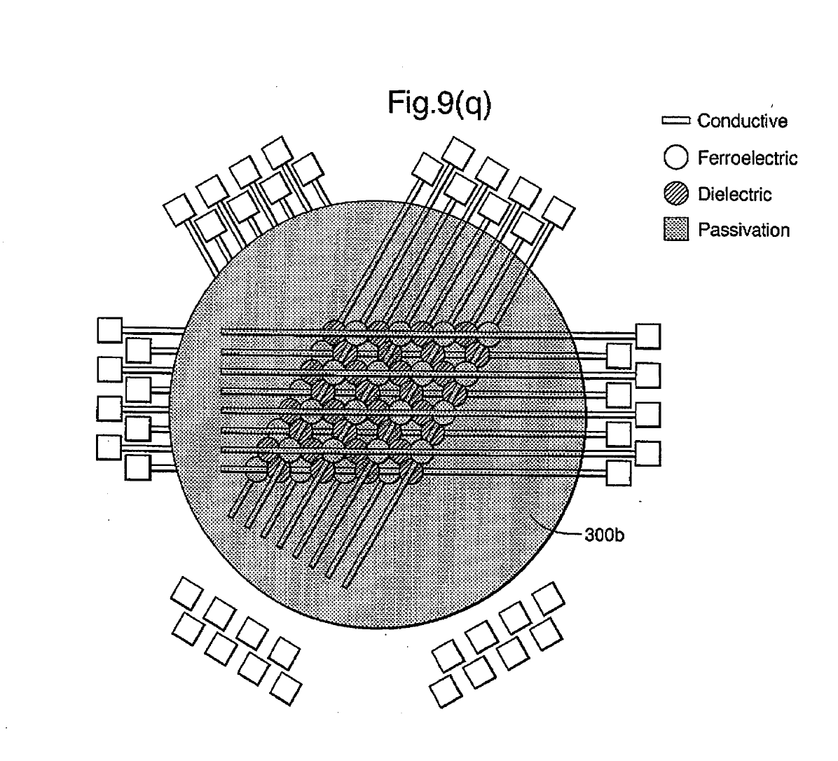

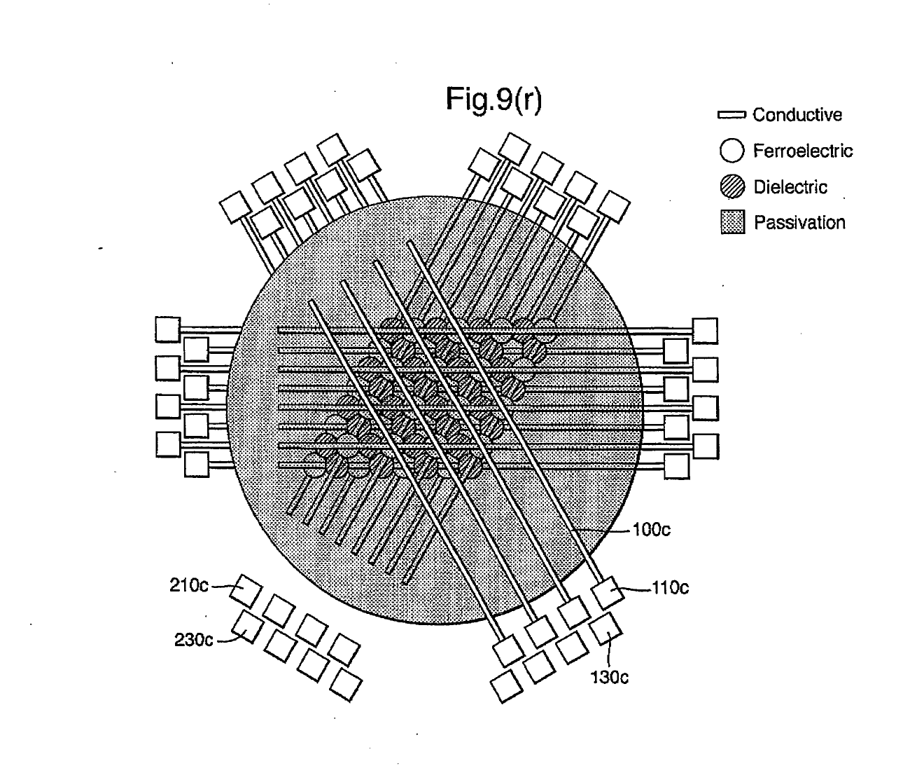

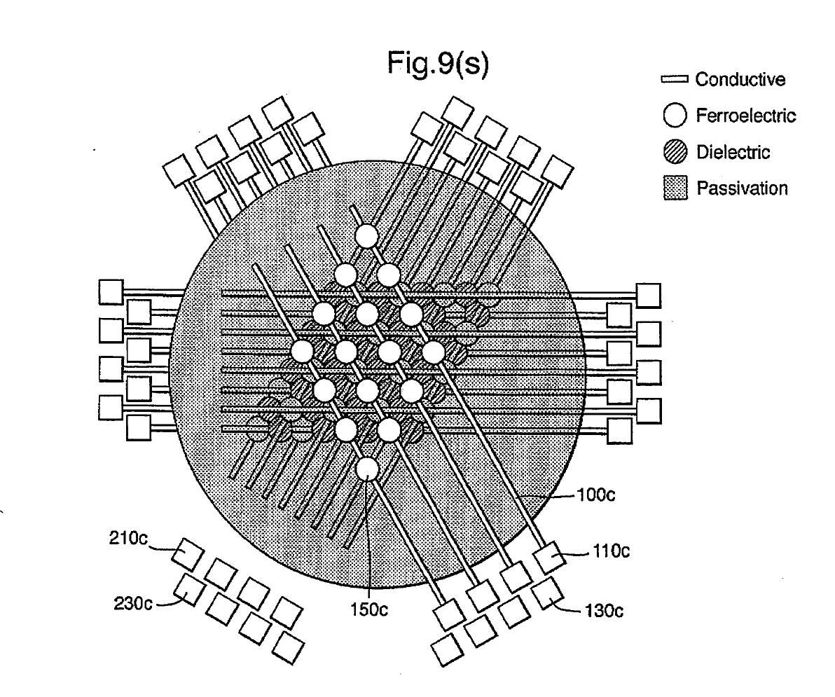

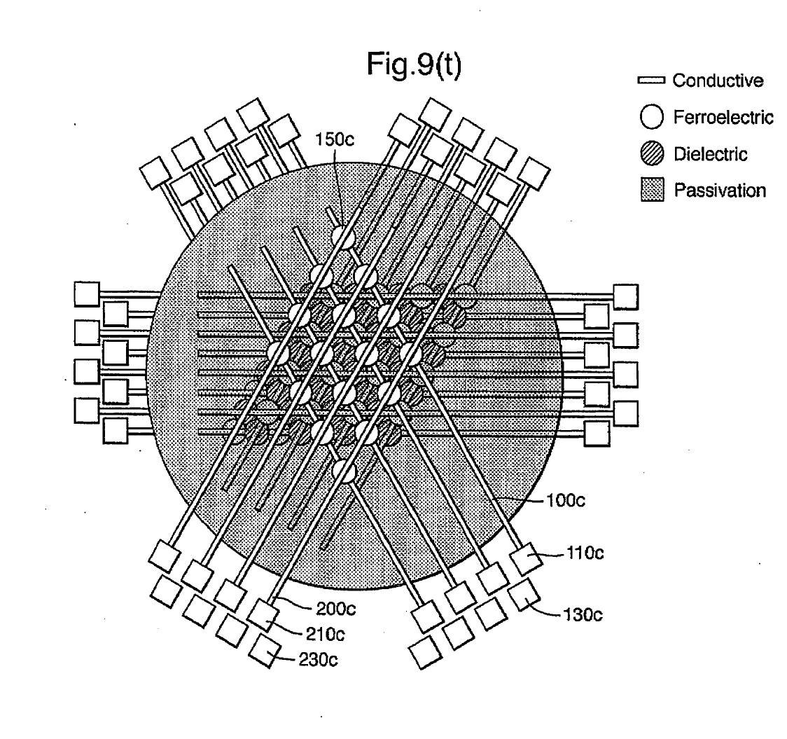

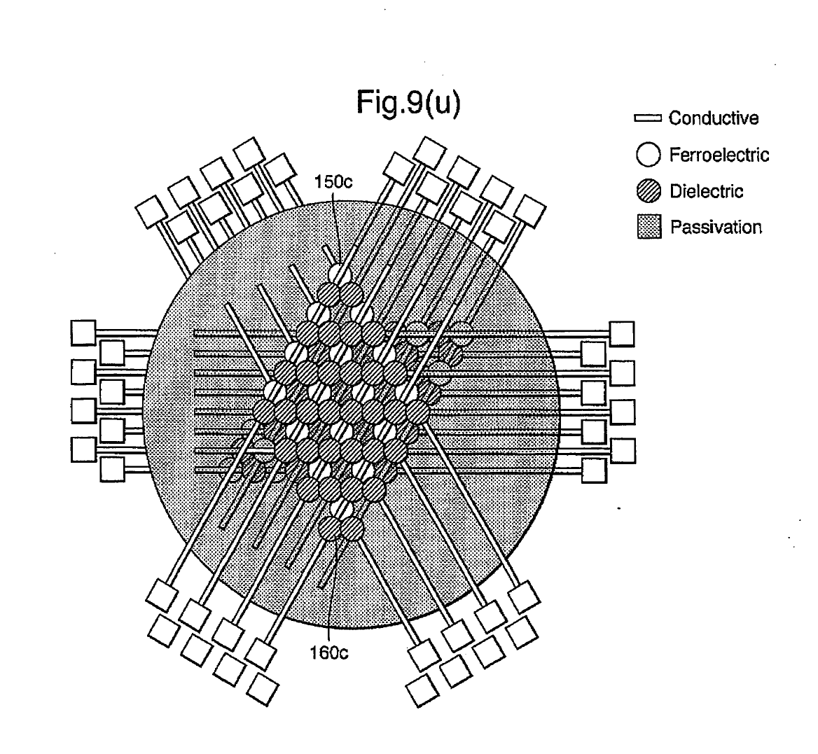

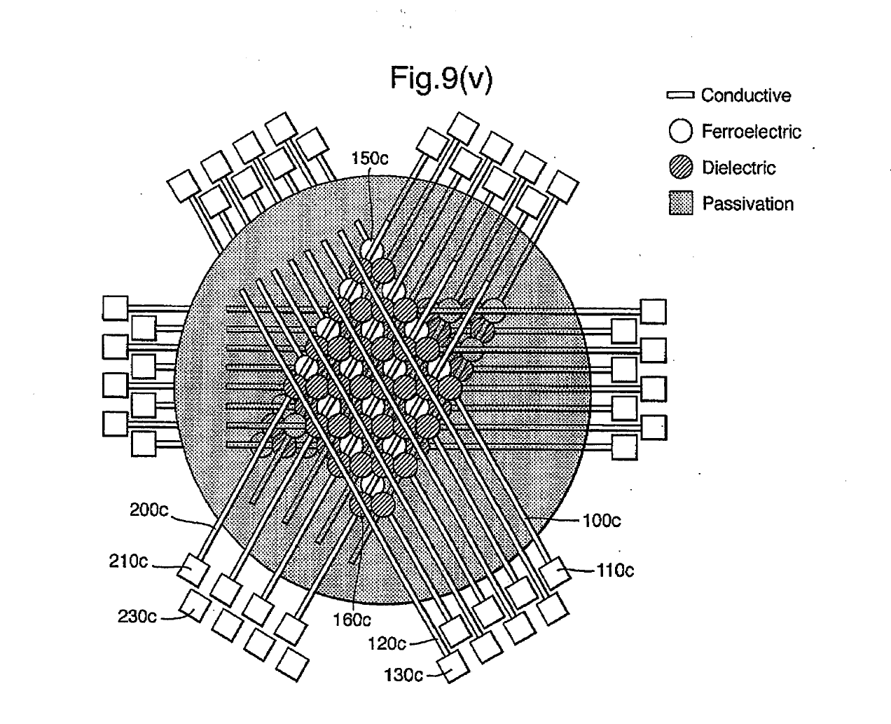

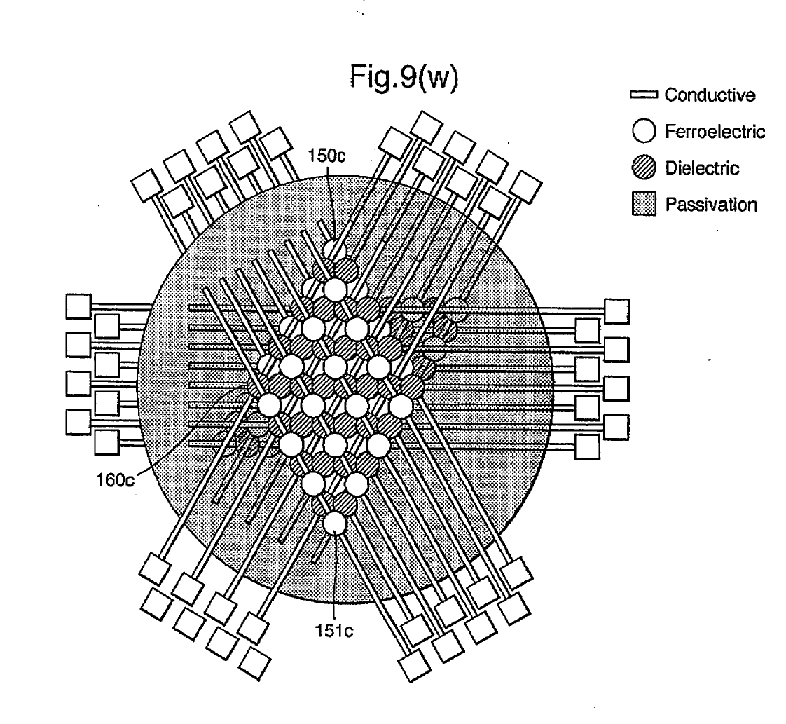

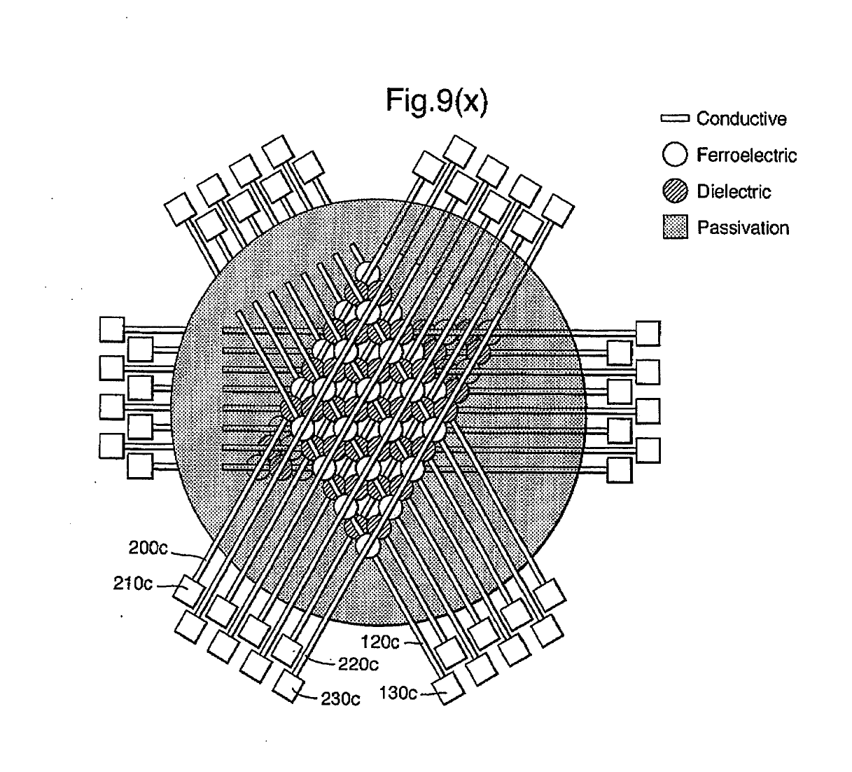

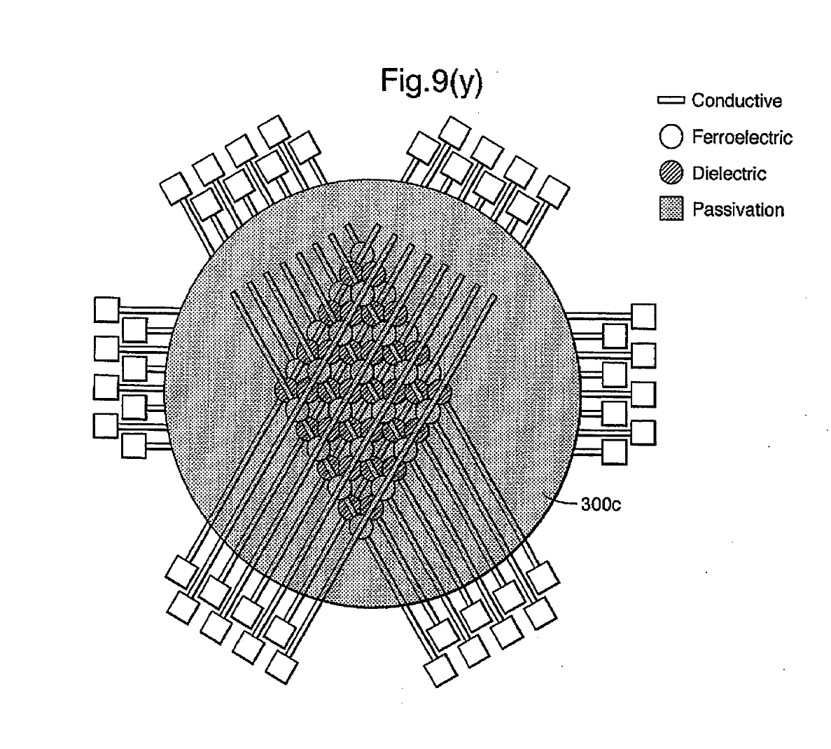

As a further example, FIGS. 9(a)-(y) show the step-by-step fabrication of a memory device comprising three stacked arrays, each array being an interlaced, double-stacked array comprising first and second sub-arrays.

Specifically, FIG. 9(a) shows groups of contact pads 110a, 130a, 210a, 230a for the first array; 110b, 130b, 210b, 230b for the second array; and 110c, 130c, 210c, 230c for the third array.

FIGS. 9(b)-(i) show the deposition of the first array. Specifically, FIG. 9(b) shows the deposition of the bottom electrodes 100a for the first sub-array of the first array; FIG. 9(c) shows the deposition of the ferroelectric 150a of the first sub-array; FIG. 9(d) shows the deposition of the top electrodes 200a of the first sub-array; FIG. 9(e) shows the deposition of the dielectric 160a for separating the first and second sub-arrays of the first array; FIG. 9(f) shows the deposition of the bottom electrodes 120a of the second sub-array of the first array; FIG. 9(g) shows the deposition of the ferroelectric 151a of the second sub-array; FIG. 9(h) shows the deposition of the top electrodes 220a of the second sub-array; and FIG. 9(i) shows the deposition of the first passivation film 300a for separating the first and second arrays.

FIGS. 9(j)-(q) show the deposition of the second array. Specifically, FIG. 9(j) shows the deposition of the bottom electrodes 100b for the first sub-array of the second array; FIG. 9(k) shows the deposition of the ferroelectric 150b of the first sub-array; FIG. 9(l) shows the deposition of the top electrodes 200b of the first sub-array; FIG. 9(m) shows the deposition of the dielectric 160b for separating the first and second sub-arrays of the second array; FIG. 9(n) shows the deposition of the bottom electrodes 120b of the second sub-array of the second array; FIG. 9(o) shows the deposition of the ferroelectric 151b of the second sub-array; FIG. 9(p) shows the deposition of the top electrodes 220b of the second sub-array; and FIG. 9(q) shows the deposition of the second passivation film 300b for separating the second and third arrays.

Finally, FIGS. 9(r)-(y) show the deposition of the third array. Specifically, FIG. 9(r) shows the deposition of the bottom electrodes 100c for the first sub-array of the third array; FIG. 9(s) shows the deposition of the ferroelectric 150c of the first sub-array; FIG. 9(t) shows the deposition of the top electrodes 200c of the first sub-array; FIG. 9(u) shows the deposition of the dielectric 160c for separating the first and second sub-arrays of the third array; FIG. 9(v) shows the deposition of the bottom electrodes 120c of the second sub-array of the third array; FIG. 9(w) shows the deposition of the ferroelectric 151c of the second sub-array; FIG. 9(x) shows the deposition of the top electrodes 220c of the second sub-array; and FIG. 9(y) shows the deposition of a third passivation film 300c for insulating the third array, if desired.

Disposing the top and bottom electrodes at angles to one another has the advantages both that a larger number of interlaced arrays can be deposited without the use of a passivation film and that the area of the intersection can be controlled and increased. For example, if the width of each of the top and bottom electrodes is W and the angle between the top and bottom electrodes is θ, then the area at the intersection is W²/sin θ. The advantage of putting top and bottom electrodes at an angle is therefore that it not only provides a solution to a multiple layered structure, but also increases the area at the cross points—hence increasing the switching charge of each ferroelectric capacitor.

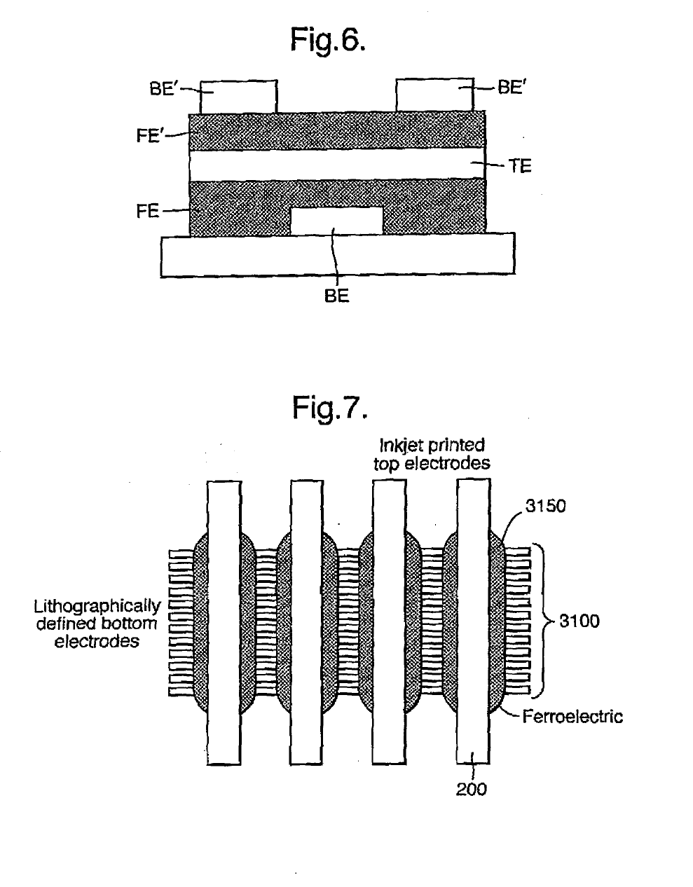

Another method of device fabrication to reduce the overall device size and complexity is to use “shared” bottom and top electrodes in a cross point device. The cross-sectional and plan views of such a device are shown in FIG. 6. The diagrams show how the bottom electrodes BE and top electrodes TE are separated by a ferroelectric layer FE thus forming one set of cross points. In addition, the top electrode TE can also act as an electrode for a second set of cross points with a second ferroelectric layer FE′ by using another set of electrodes BE′. One method of driving such a structure is by holding a fixed potential at the TE and sweeping the potentials of BE and BE′ positively or negatively as in the case for a single pair of electrodes in a conventional cell.

The fabrication of cross point arrays has been described for an inkjet printing based technique only, albeit with the possibility of depositing wetting and dielectric layers by spin coating or other suitable methods. This technique is seen as the most efficient method of reducing fabrication costs, due to the ability to fabricate devices completely from solution and without requiring complex manufacturing equipment or swapping of the substrate between different machines during the fabrication process.

It is conceivable, however, to combine conventional processes such as evaporation and lithography to fabricate electrodes with those using inkjet printing. In such a case, a set of bottom electrodes fabricated by such lithography based techniques, is acceptable in terms of device cost, since only one lithography step is required. The alignment of these patterns by a mask aligner is not required, because top electrodes can be fabricated by inkjet printing. Moreover, changes in machines during the fabrication process can be minimised.

By combining one set of electrodes defined by lithography with one by inkjet printing, a higher cross point resolution can be created than by free format inkjet printing alone. FIG. 7 shows such a device structure, in which the bottom electrodes 3100 have been lithographically defined. Regions of ferroelectric material 3150 have been inkjet printed so that each region covers all the bottom electrodes 3100. Of course, it would be possible to deposit the regions of ferroelectric material 3150 so that they each cover only a plurality, but not all, of the bottom electrodes 3100. A single top electrode 200 is inkjet printed over each region of ferroelectric material 3150. Since the top electrodes 200 are inkjet printed, their track width is broader than that of the photolithographically defined bottom electrodes 3100. Accordingly, the bottom electrodes 3100 are more densely packed and there are more of them. In this way many more cross points can be fabricated by one inkjet printed top electrode with lithographically defined bottom electrodes, than purely inkjet printing alone. A series of inkjet printed ferroelectric features are shown in the figure, but this does not need to be the case, as a spin-coated film can be incorporated. As previously described, a wetting layer may be necessary between the ferroelectric and top electrodes in order to fabricate the cross point array.

As a further alternative or in addition, the contact pads can be preformed by any suitable technique, such as photolithographic techniques, stamping, micro-embossing, flood printing, and the electrodes can be inkjet printed to connect with the contact the pads.

In short, the present invention can be used on a variety of substrates, and can be tailored to meet the requirements of an array resolution as required due to the flexibility of the additive patterning process of inkjet printing.

The current invention provides a technique by which a number of cross point arrays may be fabricated in both a laterally and a vertically stacked manner.

The impact of this technique is the potential to fabricate low cost and reliable cross point arrays by depositing materials from the liquid phase in ambient conditions. Using the materials described, it is possible to fabricate devices on a number of different substrate materials by the use of wetting layers tailored for the appropriate subsequent materials.

The foregoing description has been given by way of example only and it will be appreciated by a person skilled in the art that modifications can be made within the scope of the present invention.

In particular, the present invention has been described with particular reference to ferroelectric memories. However, the electrically functional material need not be ferroelectric and can have other or additional properties to suit the intended use of the cross point device. For example, the electrically functional material can be a light emitting material and the cross point device an LED or OLED display or photovoltaic device; or the electrically functional material can be a material suitable for forming a capacitor at the cross point(s). It should be noted that two or more different electrically functional materials could be used in a single cross point device.

What is claimed is:

1. A method of manufacturing a cross-point device, including:
providing at least one first electrode on a substrate;
providing first regions of an electrically functional material, at least one of the first regions being provided over the at least one first electrode; and
providing at least one second electrode over the at least one first electrode and the plurality of regions of electrically functional material,
the first and second electrodes forming a plurality of intersections with the electrically functional material between them, and
at least two intersections having separate regions of electrically functional material between the first and second electrodes.

2. A method of manufacturing a cross-point device, including:
providing a plurality of first electrodes on a substrate;
providing first regions of an- electrically functional material over the first electrodes; and
providing a plurality of second electrodes over the first electrodes and the first regions of electrically functional material,
the first and second electrodes forming a plurality of intersections with the electrically functional material between them, and
at least two intersections having separate regions of electrically functional material between the first and second electrodes.

3. A method according to claim 2, each intersection having a separate region of electrically functional material between the first and second electrodes.

4. A method according to claim 2, including, after providing the second electrodes:
providing a plurality of third electrodes in one of respective gaps between first electrodes and respective gaps between second electrodes;
providing second regions of electrically functional material over the third electrodes and in gaps formed between both the first electrodes and the second electrodes; and
providing a plurality of fourth electrodes over the third electrodes and in the other of the respective gaps between first electrodes and the respective gaps between second electrodes,
the third and fourth electrodes intersecting with the second regions of electrically functional material between them, and
at least two intersections of the third and fourth electrodes having separate ones of the second regions of electrically functional material disposed between the third and fourth electrodes.

5. A method according to claim 4, including, before providing the third electrodes:
providing a region of dielectric material over at least portions of the first and second electrodes that are exposed between the first regions of electrically functional material.

6. A method according to claim 2, including:
providing a further region of electrically functional material over both the second electrodes and the first regions of electrically functional material; and
providing a further electrode over the further region of electrically functional material,
said second electrodes and the further electrode forming an intersection with the further region of electrically functional material between them.

7. A method according to claim 2, the first and second electrodes and the first regions of electrically functional material forming an array, the method further including:
providing a passivation layer over the array; and
repeating the steps of claim 2 on the passivation layer to form a further array.

8. A method according to claim 7, electrodes in at least one array being at an angle other than parallel with or perpendicular to electrodes in at least one other array.

9. A method according to claim 2, at least one of the first electrodes, the second electrodes and the electrically functional material being deposited by ink jet printing.

10. A method according to claim 2, further including depositing a wetting layer on the first regions of electrically functional material before depositing the second electrodes.

11. A method according to claim 2, the first electrodes being deposited by at least one of a soft lithography technique, stamping and embossing.

12. A method according to claim 2, the first electrode being deposited by at least one of chemical vapour discharge and thermal evaporation, and then patterned by a lithographic technique.

13. A method according to claim 2, at least the second electrodes being printed using an aqueous PEDOT:PSS solution.

14. A method according to claim 2, the electrically functional material being at least one of a ferroelectric material, a light emitting material and a capacitive material.

15. A method according to claim 2, the electrically functional material including P(VDF-TrFE).

16. A method of manufacturing a cross-point device, including:
depositing an electrically functional material on a plurality of first electrodes; and
depositing a plurality second electrodes on the electrically functional material so that the first and second electrodes form a plurality of intersections,
the electrically functional material and the second electrodes being deposited by a printing process.

17. A method according to claim 16, including depositing a plurality of regions of electrically functional material.

18. A method according to claim 16, further including printing the at least one first electrode on a substrate.

19. A method according to claim 16, the deposition being carried out by inkjet printing.

20. A method of manufacturing a cross-point device, including:
depositing an electrically functional material on a first electrode;
depositing a wetting-characteristic layer on the electrically functional material; and
depositing a second electrode on the wetting-characteristic layer, the first and second electrodes intersecting one another.

21. A method of manufacturing a cross-point device, including:
providing a substrate with at least one first electrode on it;
providing an electrically functional material over the at least one first electrode; and
providing at least one second electrode over the electrically functional material,
the first and second electrodes forming at least one intersection with the electrically functionally material between them, and
the first and second electrodes being at an angle other than parallel with or perpendicular to each other.

22. A cross point device, including:
a plurality of first electrodes;
a plurality of second electrodes intersecting the first electrodes; and
a plurality of regions of electrically functional material between the first and second electrodes,
at least two intersections having separate regions of electrically functional material between the first and second electrodes.

23. A cross point device according to claim 22, each intersection having a separate region of electrically functional material between the first and second electrodes.

24. A cross-point device according to claim 22, further including:
a plurality of third electrodes in one of respective gaps between the first electrodes and respective gaps between the second electrodes, the third electrodes being electrically isolated from the others of the first electrodes and the second electrodes;
a plurality of fourth electrodes in the other of the respective gaps between the first electrodes and the respective gaps between the second electrodes, the fourth electrodes electrically being isolated from the ones of the first electrodes and the second electrodes and intersecting with the plurality of third electrodes;
a plurality of second regions of electrically functional material at intersections between the third and fourth electrodes and in gaps between the first electrodes, the second electrodes and the first regions of electrically functional material;
at least two intersections having separate second regions of electrically functional material between the third and fourth electrodes.

25. A cross-point device according to claim 24, the third and fourth electrodes being electrically isolated from the second and first electrodes respectively by means of dielectric material disposed between respective intersections of the third and fourth electrodes with the second and first electrodes.

26. A cross-point device according to claim 22, further including:
further regions of electrically functional material over both the second electrodes and the first regions of electrically functional material; and
further electrodes over the further regions of electrically functional material, the second electrodes and the further electrodes forming an intersection with the further regions of electrically functional material between them.

27. A cross-point device according to claim 22, the first electrodes, second electrodes and regions of electrically functional material forming an array, and further including:
a passivation layer over the array; and
a further array formed on the passivation layer.

28. A cross-point device according to claim 27, further including further passivation and arrays.

29. A cross-point device according to claim 27, electrodes in at least one array being at an angle other than parallel or perpendicular to electrodes in at least one other array.

30. A cross-point array according to claim 22, further including a wetting layer between the electrically functional material and the second electrodes.

31. A cross-point device according to claim 22, each region of electrically functional material overlying a plurality of first electrodes, and a single second electrode overlies each region of electrically functional material.

32. A cross-point device according to claim 22, at least the second electrode including PEDOT.

33. A cross-point device according to claim 22, the electrically functional material being at least one of a ferroelectric material, a light emitting material and a capacitive material.

34. A cross-point device according to claim 22, the electrically functional material including P(VDF-TrFE).

35. A cross point device including:
an electrically functional material on a first electrode;
a wetting-characteristic layer on the electrically functional material; and
a second electrode on the wetting-characteristic layer, the first and second electrodes intersecting one another.

36. A cross-point device, including:
a substrate with at least one first electrode on it;
an electrically functional material over the at least one first electrode; and
at least one second electrode over the electrically functional material,
the first and second electrodes forming at least one intersection with the electrically functionally material between them, and
the first and second electrodes being at an angle other than parallel or perpendicular to each other.
